(19) United States
(12) Patent Application Publication
(10) Pub. No.: US 2025/0293668 A1
(43) Pub. Date: Sep. 18, 2025

(54) TUNING-FORK-TYPE DRIVING ELEMENT AND LIGHT DEFLECTION ELEMENT

(71) Applicant: Panasonic Intellectual Property Management Co., Ltd., Osaka (JP)

(72) Inventors: Yusuke SAKATA, Osaka (JP); Kensuke MIHARA, Osaka (JP)

(21) Appl. No.: 19/225,290

(22) Filed: Jun. 2, 2025

Related U.S. Application Data
(63) Continuation of application No. PCT/JP2023/031049, filed on Aug. 28, 2023.

(30) Foreign Application Priority Data
Dec. 5, 2022 (JP) 2022-194454

(51) Int. Cl. H03H 9/205; G02B 26/08; G02B 26/10; H03H 9/02; H03H 9/15

(52) U.S. Cl. CPC H03H 9/205; G02B 26/0858; G02B 26/105; H03H 9/02259; H03H 2009/155

(57) ABSTRACT

A tuning-fork-type driving element includes: a movable part rotatable about a rotation axis; a coupling part extending from the movable part along the rotation axis; a pair of arm parts placed with the coupling part located therebetween; a support part coupling the coupling part and the pair of arm parts to a fixation part; and drive parts placed on the arm parts, respectively. The pair of arm parts each have a protrusion that overlaps a node line that occurs when the arm parts vibrate in a higher-order vibration mode higher than a first-order vibration mode or an extension line of the node line.

### CROSS REFERENCE TO RELATED APPLICATION

This application is a continuation of International Application No. PCT/JP2023/031049 filed on Aug. 28, 2023, entitled “TUNING-FORK-TYPE DRIVING ELEMENT AND LIGHT DEFLECTION ELEMENT”, which claims priority under 35 U.S.C. Section 119 of Japanese Patent Application No. 2022-194454 filed on Dec. 5, 2022, entitled “TUNING-FORK-TYPE DRIVING ELEMENT AND LIGHT DEFLECTION ELEMENT”. The disclosures of the above applications are incorporated herein by reference.

### BACKGROUND OF THE INVENTION

### Field of the Invention

The present invention relates to a tuning-fork-type driving element that rotates a movable part about a rotation axis, and a light deflection element including the tuning-fork-type driving element.

### Description of Related Art

In recent years, by using micro electro mechanical system (MEMS) technology, driving elements that rotate a movable part have been developed. In this type of driving element, a reflection surface is located on the movable part, thereby allowing scanning to be performed at a predetermined deflection angle with light incident on the reflection surface. This type of driving element is installed in image display devices such as head-up displays and head-mounted displays. In addition, this type of driving element can also be used in laser radars that use laser light to detect objects, etc.

Japanese Laid-Open Patent Publication No. 2019-082625 describes a tuning-fork-type driving element in which a movable part is rotated by a so-called tuning fork vibrator. In this driving element, the movable part is connected to the tuning fork vibrator by a first connector extending along a rotation axis. In addition, the tuning fork vibrator is perpendicularly connected to a second connector extending along the rotation axis. The second connector is connected to a base. The base constitutes a fixation part for fixing the driving element to an installation surface. By driving the tuning fork vibrator, the movable part is rotated about the rotation axis, and a reflection surface located on the movable part is rotated accordingly.

The tuning-fork-type driving element can be driven in a higher-order vibration mode higher than a first-order vibration mode in order to vibrate the movable part at a higher frequency. In this case, if the natural frequency of the higher-order vibration mode is close to an integer multiple of the natural frequency of the first-order vibration mode, the first-order vibration mode influences the higher-order vibration mode, causing a problem in the operation of the tuning-fork-type vibrator.

In contrast, for example, the natural frequency of the first-order vibration mode can be changed by changing the length or thickness of the tuning fork vibrator. However, in this method, the natural frequency of a second-order vibration mode also changes at the same time, so that it is difficult to design such that the natural frequency of the higher-order vibration mode is the target frequency while changing the natural frequency of the first-order vibration mode.

### SUMMARY OF THE INVENTION

A tuning-fork-type driving element according to a first aspect of the present invention includes: a movable part rotatable about a rotation axis; a coupling part extending from the movable part along the rotation axis; a pair of arm parts placed with the coupling part located therebetween; a support part coupling the coupling part and the pair of arm parts to a fixation part; and drive parts placed on the arm parts, respectively. The pair of arm parts each have a protrusion that overlaps a node line that occurs when the arm parts vibrate in a higher-order vibration mode higher than a first-order vibration mode or an extension line of the node line.

In the tuning-fork-type driving element according to this aspect, the natural frequency of a lower-order vibration mode can be changed by the protrusion which is a mass portion, and the natural frequency of the lower-order vibration mode can be controlled by adjusting the mass of the protrusion by the length, etc., of the protrusion. In addition, since the protrusion which is a mass portion is formed on the node line or the extension line of the node line, the influence of the mass of the protrusion on the natural frequency of the higher-order vibration mode can be suppressed. Therefore, the natural frequency of the lower-order vibration mode lower than the higher-order vibration mode can be easily adjusted to a frequency that is less likely to influence the higher-order vibration mode, without making the natural frequency of the higher-order vibration mode greatly different from the target frequency.

A light deflection element according to a second aspect of the present invention includes the tuning-fork-type driving element according to the first aspect and a reflection surface located on the movable part.

In the light deflection element according to this aspect, since the light deflection element includes the tuning-fork-type driving element according to the first aspect, the reflection surface can be smoothly and stably vibrated in the higher-order vibration mode. Therefore, light incident on the reflection surface can be stably deflected as the movable part vibrates.

A tuning-fork-type driving element according to a third aspect of the present invention includes: a pair of arm parts placed with a rotation axis located therebetween; a support part coupling the pair of arm parts to a fixation part; and drive parts placed on the arm parts, respectively. The pair of arm parts each have a protrusion that overlaps a node line that occurs when the arm parts vibrate in a higher-order vibration mode higher than a first-order vibration mode or an extension line of the node line, or a recess that overlaps the node line.

In the tuning-fork-type driving element according to this aspect, the same effects as those of the first aspect are achieved.

A light deflection element according to a fourth aspect of the present invention includes the tuning-fork-type driving element according to the third aspect and a reflection surface located on the movable part.

In the tuning-fork-type driving element according to this aspect, the same effects as those of the second aspect are achieved.

The effects and the significance of the present invention will be further clarified by the description of the embodiments below. However, the embodiments below are merely examples for implementing the present invention. The present invention is not limited to the description of the embodiments below in any way.

### BRIEF DESCRIPTION OF THE DRAWINGS

FIG. 1 is a plan view schematically showing configurations of a tuning-fork-type driving element and a light deflection element according to Embodiment 1;

FIG. 2 is a cross-sectional view of a C1-C2 cross-section as seen in an X-axis negative direction, according to Embodiment 1;

FIG. 3A is a plan view schematically showing a configuration of a tuning-fork-type driving element according to verification of a comparative example;

FIG. 3B and FIG. 3C show actual measurement results of waveforms indicating the position of a distal end of each arm part according to the verification of the comparative example;

FIG. 4A to FIG. 4C are each a plan view schematically showing a configuration of each arm part when the length of each protrusion was varied, according to simulation of Embodiment 1;

FIG. 5A to FIG. 5C are diagrams showing simulation results when the length of each protrusion was varied, respectively, according to the simulation of Embodiment 1;

FIG. 6A to FIG. 6C are each a plan view schematically showing a configuration of each arm part when the position of each protrusion was varied, according to simulation of Embodiment 1;

FIG. 7A to FIG. 7C are diagrams showing simulation results when the position of each protrusion was varied, respectively, according to the simulation of Embodiment 1;

FIG. 8 is a plan view schematically showing configurations of a tuning-fork-type driving element and a light deflection element according to Embodiment 2;

FIG. 9A to FIG. 9C are each a plan view schematically showing a configuration of each arm part when the length of each protrusion was varied, according to simulation of Embodiment 2;

FIG. 10A to FIG. 10C are diagrams showing simulation results when the length of each protrusion was varied, respectively, according to the simulation of Embodiment 2;

FIG. 11A to FIG. 11C are each a plan view schematically showing a configuration of each arm part when the length and the width of each protrusion were varied while the mass of each protrusion was kept constant, according to simulation of Embodiment 2;

FIG. 12A to FIG. 12C are diagrams showing simulation results when the length and the width of each protrusion were varied while the mass of each protrusion was kept constant, according to the simulation of Embodiment 2;

FIG. 13A to FIG. 13C are each a plan view schematically showing a configuration of each arm part when the length of each protrusion was varied while the sum of the lengths of the protrusions was kept constant, according to simulation of Embodiment 2;

FIG. 14A to FIG. 14C are diagrams showing simulation results showing a displacement amount in a Z-axis direction when the length of each protrusion was varied while the sum of the lengths of the protrusions was kept constant, respectively, according to the simulation of Embodiment 2;

FIG. 15A to FIG. 15C are diagrams showing simulation results when the length of each protrusion was varied while the sum of the lengths of the protrusions was kept constant, according to the simulation of Embodiment 2;

FIG. 16A to FIG. 16C are each a plan view schematically showing a configuration of each arm part when the position of each protrusion was shifted in an X-axis direction from a position on an extension line of a node line, according to simulation of Embodiment 2;

FIG. 17A to FIG. 17C are diagrams showing simulation results showing a displacement amount in the Z-axis direction when the position of each protrusion was shifted in the X-axis direction from the position on the extension line of the node line, respectively, according to the simulation of Embodiment 2;

FIG. 18A to FIG. 18C are each a plan view schematically showing a configuration of each arm part when the position of each protrusion was shifted in the X-axis direction from a position on an extension line of a node line, according to simulation of a comparative example;

FIG. 19A to FIG. 19C are diagrams showing simulation results showing a displacement amount in the Z-axis direction when the position of each protrusion was shifted in the X-axis direction from the position on the extension line of the node line, respectively, according to the simulation of the comparative example;

FIG. 20A to FIG. 20C are each a plan view schematically showing a configuration of a first drive unit according to a modification of the protrusions;

FIG. 21A to FIG. 21C are each a plan view schematically showing a configuration of a first drive unit according to a modification of the protrusions;

FIG. 22A and FIG. 22B are each a plan view schematically showing a configuration of a first drive unit according to a modification of the protrusions;

FIG. 23A is a plan view (back view) schematically showing a configuration of a first drive unit according to another modification of each protrusion;

FIG. 23B is a plan view (back view) schematically showing a configuration of a first drive unit in which a recess is provided at the position of each node line, according to another modification in which a recess is provided at the position of each arm part corresponding to each node line;

FIG. 24A to FIG. 24C show simulation results showing a displacement amount in the Z-axis direction when each arm part was driven in a second-order vibration mode, a third-order vibration mode, and a fourth-order vibration mode, respectively, according to a modification of a higher-order vibration mode;

FIG. 25A to FIG. 25C show simulation results showing a displacement amount in the Z-axis direction when each arm part was driven in the second-order vibration mode, the third-order vibration mode, and the fourth-order vibration mode, respectively, according to a modification of the higher-order vibration mode;

FIG. 26A to FIG. 26C show simulation results showing a displacement amount in the Z-axis direction when each arm part was driven in the second-order vibration mode, the third-order vibration mode, and the fourth-order vibration mode, respectively, according to a modification of the higher-order vibration mode;

FIG. 27A and FIG. 27B show simulation results showing a displacement amount in the Z-axis direction when each arm part was driven in the second-order vibration mode and the third-order vibration mode, respectively, according to a modification of the higher-order vibration mode;

FIG. 28 is a plan view schematically showing configurations of a tuning-fork-type driving element and a light deflection element according to another modification; and

FIG. 29 is a plan view schematically showing a configuration of a tuning-fork-type driving element according to still another modification.

It should be noted that the drawings are solely for description and do not limit the scope of the present invention by any degree.

### DETAILED DESCRIPTION

Hereinafter, embodiments of the present invention will be described with reference to the drawings. For convenience, in each drawing, X, Y, and Z axes that are orthogonal to each other are additionally shown. The Z-axis positive direction is the vertical upward direction.

### Embodiment 1

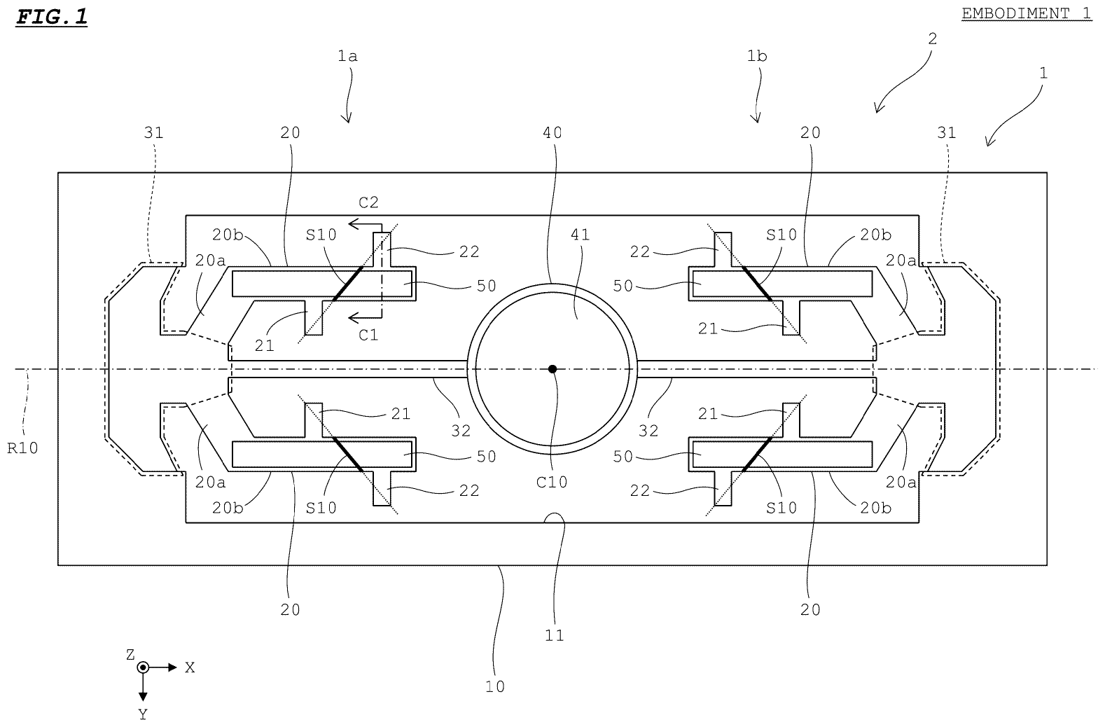

FIG. 1 is a plan view schematically showing configurations of a tuning-fork-type driving element 1 and a light deflection element 2.

The tuning-fork-type driving element 1 includes a first drive unit 1a, a second drive unit 1b, a fixation part 10, and a movable part 40. The first drive unit 1a and the second drive unit 1b each include a pair of arm parts 20 aligned in the Y-axis direction, a support part 31, a coupling part 32, and a pair of drive parts 50. The tuning-fork-type driving element 1 is configured to be symmetrical in the X-axis direction and the Y-axis direction about a center C10 thereof in a plan view. The light deflection element 2 is configured by forming a reflection surface 41 on the upper surface of the movable part 40.

The first drive unit 1a and the second drive unit 1b rotate the movable part 40 about a rotation axis R10 in response to a drive voltage supplied to each drive part 50 from a drive circuit which is not shown. The reflection surface 41 reflects light incident thereon from above the movable part 40, in a direction corresponding to the deflection angle of the movable part 40. Accordingly, as the movable part 40 rotates, the light (e.g., laser light) incident on the reflection surface 40 is deflected and scanning is performed with this light.

The fixation part 10 is configured in a frame shape. The four arm parts 20 and the pair of coupling parts 32 are located in an opening 11 that penetrates the fixation part 10 in the Z-axis direction at the center of the fixation part 10 in a plan view, and are placed between the fixation part 10 and the movable part 40. The first drive unit 1a and the second drive unit 1b are placed on the X-axis positive side and the X-axis negative side of the movable part 40, respectively. The pair of arm parts 20 of each of the first drive unit 1a and the second drive unit 1b have a tuning fork shape in a plan view.

Each arm part 20 has a substantially L-shape in a plan view. The pair of arm parts 20 aligned in the Y-axis direction are placed with the coupling part 32 located therebetween. Each arm part 20 has a first portion 20a that extends in a direction away from the rotation axis R10, and a second portion 20b that extends from an end portion of the first portion 20a in a direction approaching the movable part 40 (in the X-axis direction). The first portion 20a is connected to the support part 31 on the side opposite to the second portion 20b. Each drive part 50 is mainly placed on the upper surface of the second portion 20b. Here, the first portion 20a extends in the direction approaching the movable part 40 at a predetermined angle with respect to a direction perpendicular to the rotation axis R10. The first portion 20a may extend in the direction perpendicular to the rotation axis R10.

A protrusion 21 is formed on the inner surface of the second portion 20b on the rotation axis R10 side so as to extend in the direction approaching the rotation axis R10. A protrusion 22 is formed on the outer surface of the second portion 20b on the side opposite to the rotation axis R10 so as to extend in the direction away from the rotation axis R10. Specifically, the protrusion 21 extends in a direction perpendicular to the second portion 20b (in the Y-axis direction) at the inner surface of the second portion 20b, and the protrusion 22 extends in the direction perpendicular to the second portion 20b (in the Y-axis direction) at the outer surface of the second portion 20b. In addition, the protrusions 21 and 22 are formed so as to overlap an extension line of a node line S10 described later in a plan view. In FIG. 1, each node line S10 is indicated by a bold solid line, and the extension line of each node line S10 is indicated by a dotted line.

Each support part 31 couples the coupling part 32 and the pair of arm parts 20, which are aligned in the Y-axis direction, to the fixation part 10. The outer edge of the support part 31 on the outer side in the X-axis direction is connected to the fixation part 10. Each coupling part 32 extends in the X-axis direction along the rotation axis R10 from the movable part 40. An end portion on the outer side in the X-axis direction of the coupling part 32 is connected to the support part 31. End portions on the X-axis positive side and the X-axis negative side of the movable part 40 are connected to end portions on the inner side in the Y-axis direction of the pair of coupling parts 32.

The movable part 40 has a circular shape in a plan view. The movable part 40 is supported by the fixation part 10 via the pair of support parts 31 and the pair of coupling parts 32 so as to be rotatable about the rotation axis R10. The center of the movable part 40 coincides with the position of the center C10 of the tuning-fork-type driving element 1.

An optical reflection film is formed on the upper surface of the movable part 40. The optical reflection film is made of a material having a high reflectance (for example, a metal or metal compound such as gold, silver, copper, or aluminum, or silicon dioxide, titanium dioxide, or the like). The optical reflection film may be composed of a dielectric multilayer film. By forming the optical reflection film on the upper surface of the movable part 40, the upper surface of the optical reflection film constitutes the reflection surface 41 that reflects light. The reflection surface 41 may be composed of the upper surface of the movable part 40.

Each drive part 50 is formed on the upper surface of the arm part 20. The drive part 50 is connected to an electrode on the fixation part 10 via a wire on the arm part 20, the support part 31, and the fixation part 10. A cable (external wire) connected to an external device is connected to the electrode on the fixation part 10 by wire bonding.

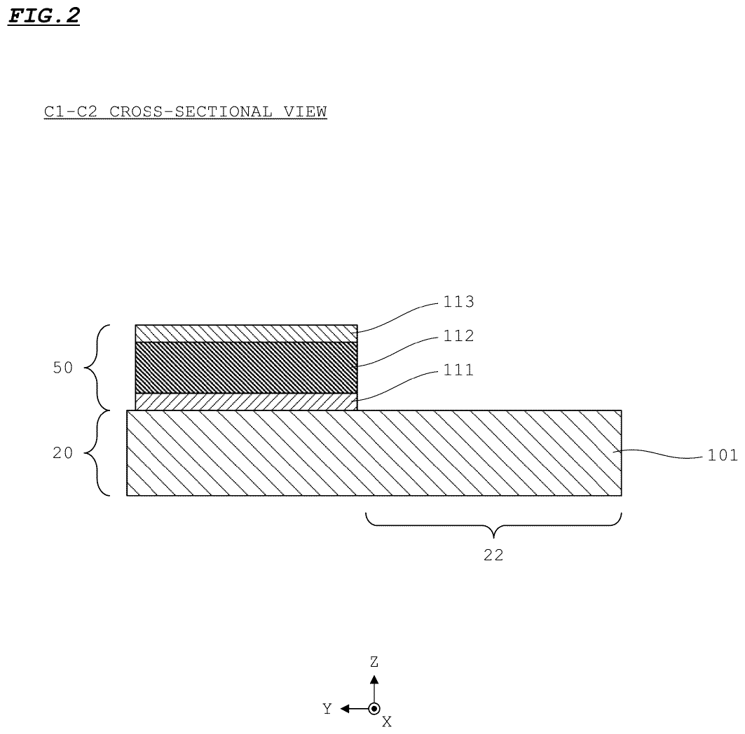

When a drive voltage is applied to each drive part 50, a piezoelectric layer 112 (see FIG. 2) in the drive part 50 becomes deformed due to an inverse piezoelectric effect, so that the arm part 20 on which the drive part 50 is placed vibrates so as to bend. At this time, drive voltages having phases opposite to each other are applied to two drive parts 50 aligned in the Y-axis direction, and drive voltages having the same phase are applied to two drive parts 50 aligned in the X-axis direction. Accordingly, the pair of arm parts 20 located on the Y-axis positive side of the rotation axis R10 and the pair of arm parts 20 located on the Y-axis negative side of the rotation axis R10 bend in directions opposite to each other. Accordingly, due to the deformation of the four arm parts 20, the movable part 40 rotates about the rotation axis R10.

FIG. 2 is a cross-sectional view of a C1-C2 cross-section of FIG. 1 as seen in the X-axis negative direction.

The arm part 20 is composed of a base layer 101. The drive part 50 is formed on the upper surface of the arm part 20 and has a layer structure composed of a lower electrode layer 111, the piezoelectric layer 112, and an upper electrode layer 113. The base layer 101 is made of silicon (Si), for example. The lower electrode layer 111 is made of platinum (Pt), for example. The piezoelectric layer 112 is a piezoelectric thin film, and the piezoelectric thin film is made of PZT (lead zirconate titanate: Pb(Zr,Ti)O₃), for example. The upper electrode layer 113 is made of gold (Au), for example.

Each protrusion 22 is formed by the base layer 101 of the arm part 20 protruding in the Y-axis negative direction and is integrally formed with the arm part 20. Each protrusion 21 is also formed in the same manner as each protrusion 22. That is, each protrusion 21 is formed by the base layer 101 of the arm part 20 protruding in the Y-axis positive direction and is integrally formed with the arm part 20.

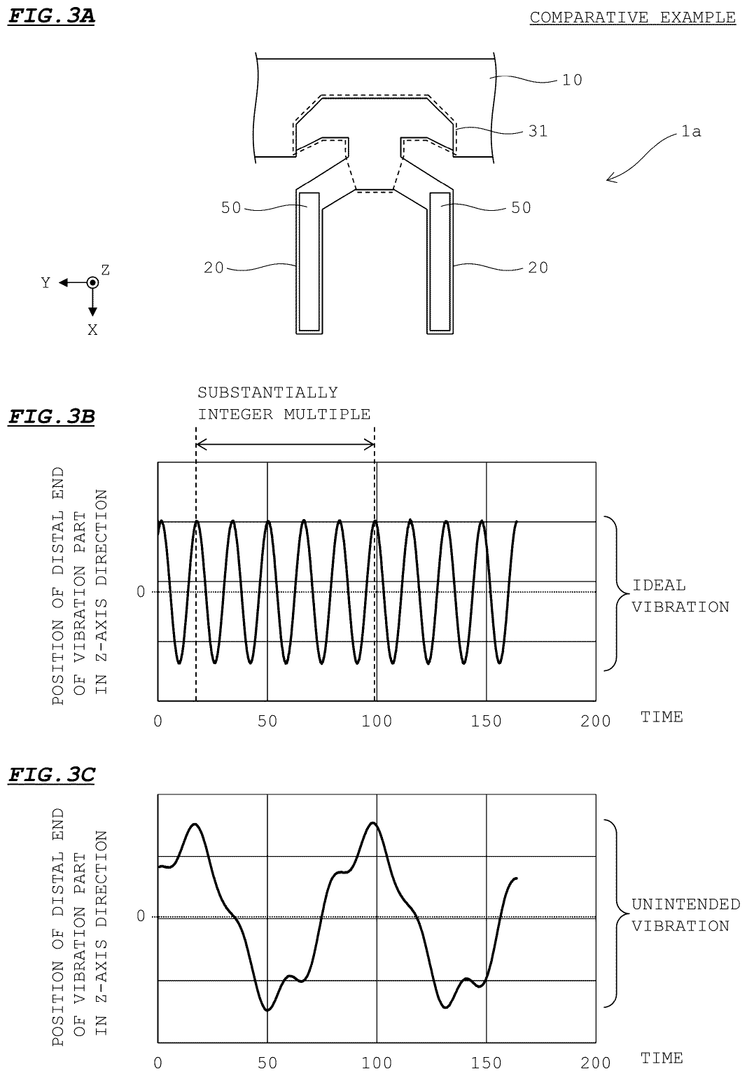

Here, in Embodiment 1, each arm part 20 is driven in a second-order vibration mode in order to vibrate the movable part 40 at a higher frequency. According to the study by the inventors, it has been found that, when each arm part 20 is driven in the second-order vibration mode as described above, if the natural frequency of the second-order vibration mode is close to an integer multiple of the natural frequency of a first-order vibration mode, the first-order vibration mode influences the second-order vibration mode, causing a problem in the operation of the tuning-fork-type driving element 1. Such a problem will be described below with reference to verification of a comparative example shown in FIG. 3A to FIG. 3C.

FIG. 3A is a plan view schematically showing a configuration of a tuning-fork-type driving element 1 according to the verification of the comparative example. FIG. 3B and FIG. 3C show actual measurement results of waveforms indicating the position in the Z-axis direction of the distal end of each arm part 20 according to the verification of the comparative example.

As shown in FIG. 3A, the tuning-fork-type driving element 1 of the comparative example includes a first drive unit 1a and a fixation part 10 around a support part 31. In this case, the coupling part 32 is omitted from the first drive unit 1a. In the comparative example, unlike Embodiment 1, no protrusions 21 and 22 are formed on each arm part 20.

In the verification of the comparative example, the shape of each arm part 20, etc., were adjusted such that the natural frequency of the arm part 20 by the second-order vibration mode was 62984.3 Hz, as shown in the waveform in FIG. 3B. If each arm part 20 vibrates only in the second-order vibration mode, the vibration of the arm part 20 at this time is ideal vibration.

However, in practice, in addition to vibration by the second-order vibration mode, vibration by the first-order vibration mode is added. In the verification of the comparative example, the natural frequency of the arm part 20 by the first-order vibration mode at this time was 12240 Hz. In this case, the natural frequency of the second-order vibration mode is 5.15 times the natural frequency of the first-order vibration mode.

When the natural frequency of the second-order vibration mode is substantially an integer multiple of the natural frequency of the first-order vibration mode as described above, the second-order vibration mode and the first-order vibration mode occur simultaneously. As a result, the vibration by the second-order vibration mode is superimposed with the vibration by the first-order vibration mode, so that unintended vibration occurs as shown in the waveform in FIG. 3C. Such unintended vibration can cause damage to the arm parts 20.

In contrast, by adjusting the shape of each arm part 20, etc., such that the natural frequency of the second-order vibration mode is not substantially an integer multiple of the natural frequency of the first-order vibration mode, the natural frequency of the first-order vibration mode can be changed. However, in this method, the natural frequency of the second-order vibration mode also changes at the same time, so that it is difficult to design such that the natural frequency of the second-order vibration mode is the target frequency while changing the natural frequency of the first-order vibration mode.

Therefore, in Embodiment 1, first, the natural frequency of the second-order vibration mode is set to the target frequency. Due to the second-order vibration mode, on each arm part 20, the node line S10 is formed as shown in FIG. 1, for example. The vibration in the Z-axis direction of the arm part 20 caused by the second-order vibration mode is substantially zero at the position of the node line S10. That is, the node line S10 means a line along a node portion where there is almost no amplitude in the direction of vibration when the arm part 20 is vibrated at the target natural frequency (in the second-order vibration mode).

After that, the natural frequency of the first-order vibration mode is adjusted by adjusting the positions, the lengths, the widths, etc., of the protrusions 21 and 22 which are placed so as to overlap the extension line (dotted line in FIG. 1) of each node line S10. At this time, since the protrusions 21 and 22 which are mass portions are formed on the extension line of each node line S10, the influence of the masses of the protrusions 21 and 22 on the natural frequency of the second-order vibration mode can be suppressed. Therefore, the natural frequency of the first-order vibration mode can be easily adjusted to a frequency that is less likely to influence the second-order vibration mode, without making the natural frequency of the second-order vibration mode greatly different from the target frequency.

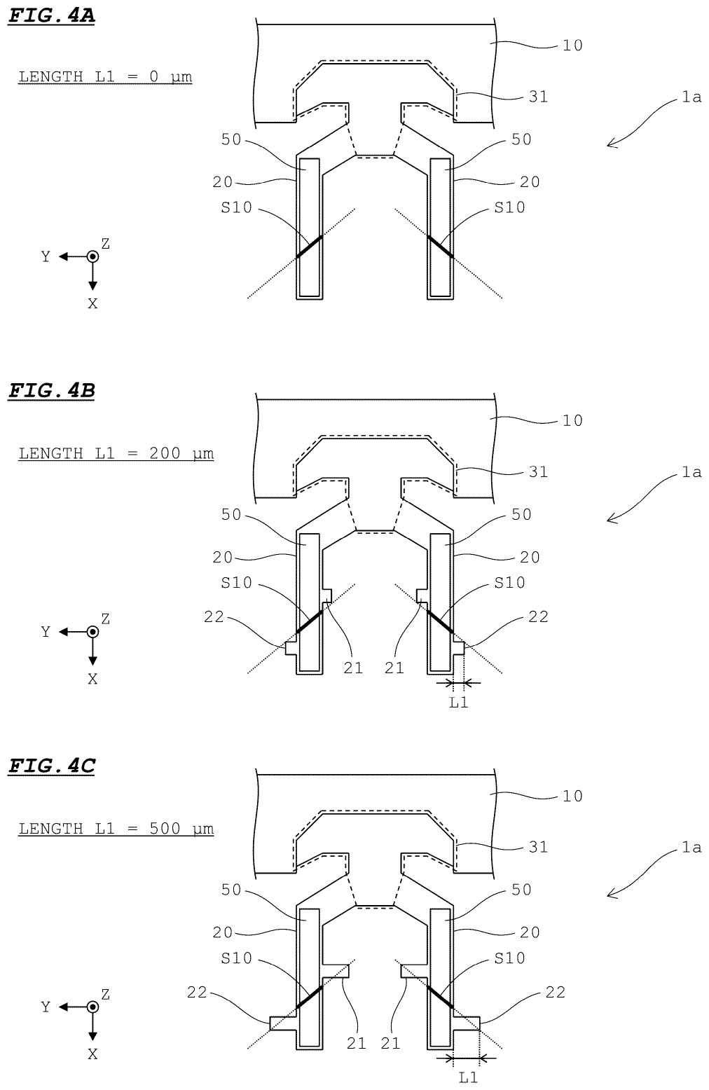

Next, an example in which the configurations of the protrusions 21 and 22 are adjusted such that the influence of the first-order vibration mode is suppressed in Embodiment 1 will be described with reference to FIG. 4A to FIG. 7C. The inventors obtained a ratio FR of the natural frequency of the second-order vibration mode to the natural frequency of the first-order vibration mode while varying the lengths and the positions of the protrusions 21 and 22 through simulation.

A tuning-fork-type driving element 1 according to simulation of Embodiment 1 described below includes a first drive unit 1a and a fixation part 10 around a support part 31 as shown in FIG. 4B, for example. In this case, the coupling part 32 is omitted from the first drive unit 1a.

FIG. 4A to FIG. 4C are each a plan view schematically showing a configuration of each arm part 20 when a length L1 of each protrusion 21 or 22 was varied, according to the simulation of Embodiment 1. FIG. 4A shows the same configuration as the comparative example shown in FIG. 3A for comparison.

FIG. 4A to FIG. 4C show states where the length L1 of each protrusion 21 or 22 was 0 μm, 200 μm, and 500 μm, respectively. The length L1 is the length in the Y-axis direction of each protrusion 21 or 22 that protrudes in the Y-axis direction from the arm part 20. In this simulation, the length of each protrusion 21 and the length of each protrusion 22 are both L1. The protrusions 21 and 22 are placed so as to overlap an extension line of each node line S10.

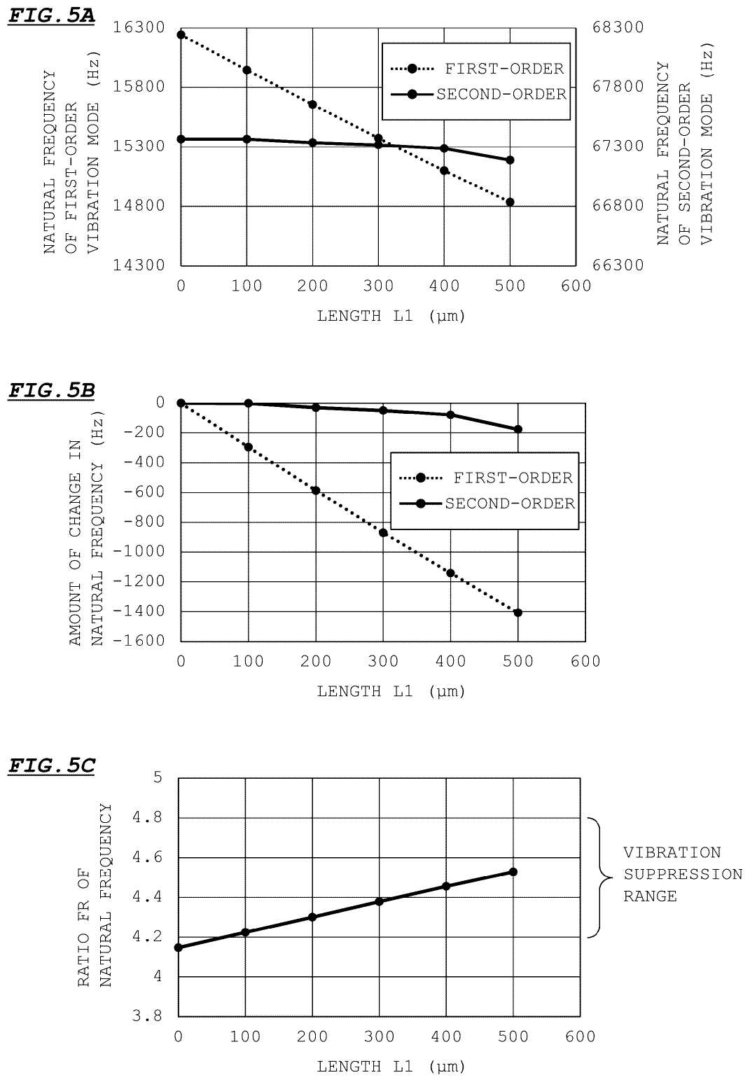

FIG. 5A to FIG. 5C are diagrams showing simulation results when the length L1 of each protrusion 21 or 22 was varied in the range of 0 μm to 500 μm in the configurations in FIG. 4A to FIG. 4C.

FIG. 5A is a graph showing the natural frequency of the first-order vibration mode and the natural frequency of the second-order vibration mode when the length L1 of each protrusion 21 or 22 was varied in the range of 0 μm to 500 μm. FIG. 5B is a graph showing the amounts of change in the natural frequencies of the first-order and second-order vibration modes when the length L1 of each protrusion 21 or 22 was varied in the range of 0 μm to 500 μm.

As shown in FIG. 5A and FIG. 5B, the amount of change in the natural frequency of the first-order vibration mode varies greatly in accordance with the change of the length L1 of each protrusion 21 or 22. Meanwhile, the amount of change in the natural frequency of the second-order vibration mode (amount of change with respect to the target frequency) almost does not change even when the length L1 of each protrusion 21 or 22 changes. This is because the protrusions 21 and 22 are placed so as to overlap the extension line of each node line S10. However, when the length L1 increases, unnecessary vibration based on the protrusions 21 and 22 occurs, and thus the amount of change in the natural frequency of the second-order vibration mode increases slightly.

FIG. 5C is a graph showing the ratio FR of the natural frequency when the length L1 of each protrusion 21 or 22 was varied in the range of 0 μm to 500 μm.

As shown in FIG. 5C, when the length L1 of each protrusion 21 or 22 changes, the ratio FR of the natural frequency also changes. As described above, if the natural frequency of the second-order vibration mode is close to an integer multiple of the natural frequency of the first-order vibration mode, that is, if the ratio FR of the natural frequency is close to an integer, the first-order vibration mode influences the second-order vibration mode, causing a problem in the operation of the tuning-fork-type driving element 1.

Therefore, when the ratio FR changes as shown in FIG. 5C, the ratio FR is preferably away from an integer such as 4 or 5 and is preferably a value within a vibration suppression range between 4.2 and 4.8. In this case, the ratio FR is most preferably the intermediate value between adjacent integers (in the case of FIG. 5C, about 4.5). When the ratio FR is a value within the vibration suppression range, the influence of the first-order vibration mode can be suppressed, thereby allowing the tuning-fork-type driving element 1 to operate normally.

When setting the ratio FR to a preferable value as described above, first, by adjusting the length, the width, the thickness, etc., of each arm part 20, the tuning-fork-type driving element 1 is designed such that the natural frequency of the second-order vibration mode is the target frequency. Then, by adjusting the length L1 of each protrusion 21 or 22 which is provided on the extension line of each node line S10 in the second-order vibration mode, the tuning-fork-type driving element 1 is designed such that the ratio FR is a value away from an integer value. At this time, since the protrusions 21 and 22 are placed so as to overlap the extension line of each node line S10, even if the length L1 of each protrusion 21 or 22 is changed, the natural frequency of the second-order vibration mode does not deviate greatly from the target frequency. Therefore, by adjusting the natural frequency of the first-order vibration mode, the tuning-fork-type driving element 1 can be easily designed such that the ratio FR is a value away from an integer value.

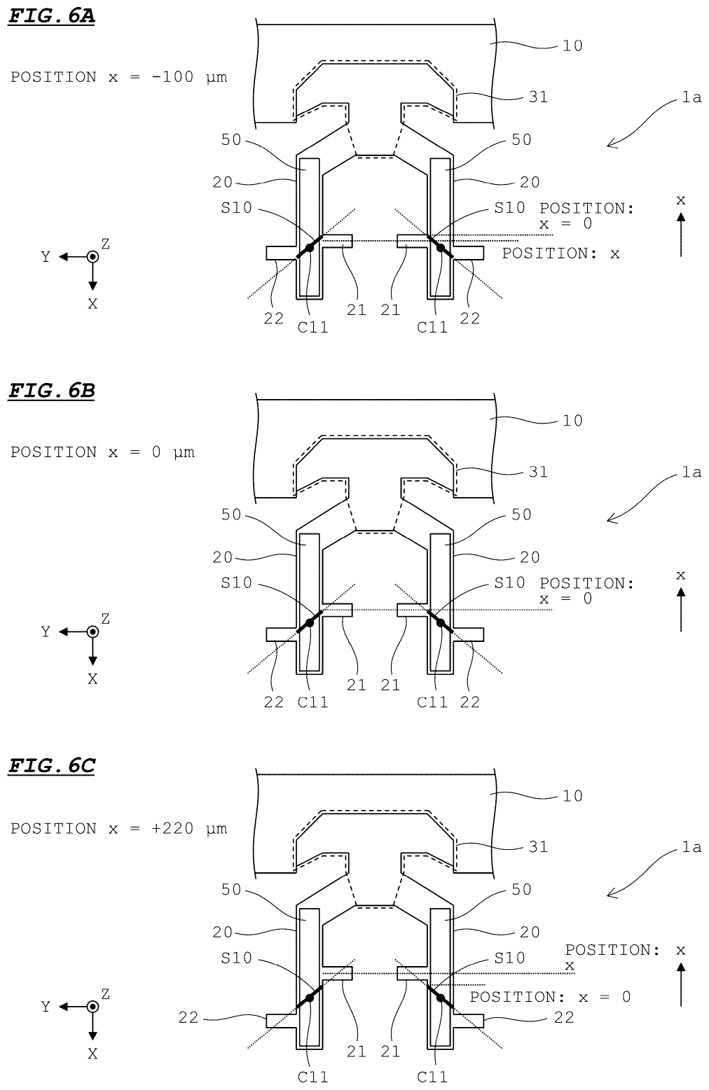

FIG. 6A to FIG. 6C are each a plan view schematically showing a configuration of each arm part 20 when a position x of each protrusion 21 or 22 was varied, according to simulation of Embodiment 1.

FIG. 6A to FIG. 6C show states where the position x of each protrusion 21 or 22 was −100 μm, 0 μm, and +220 μm, respectively. The position x is the coordinate of the center position in the X-axis direction of each protrusion 21 or 22 when the position where the node line S10 intersects a side of the arm part 20 that extends in the X-axis direction is defined as an origin. In FIG. 6A to FIG. 6C, the position x of the protrusion 21 on the Y-axis negative side is shown for convenience. When the position where the node line S10 passes through the center in the Y-axis direction of the arm part 20 is defined as a center C11, the protrusions 21 and 22 provided on one arm part 20 are configured to be point-symmetrical about the center C11 in this simulation.

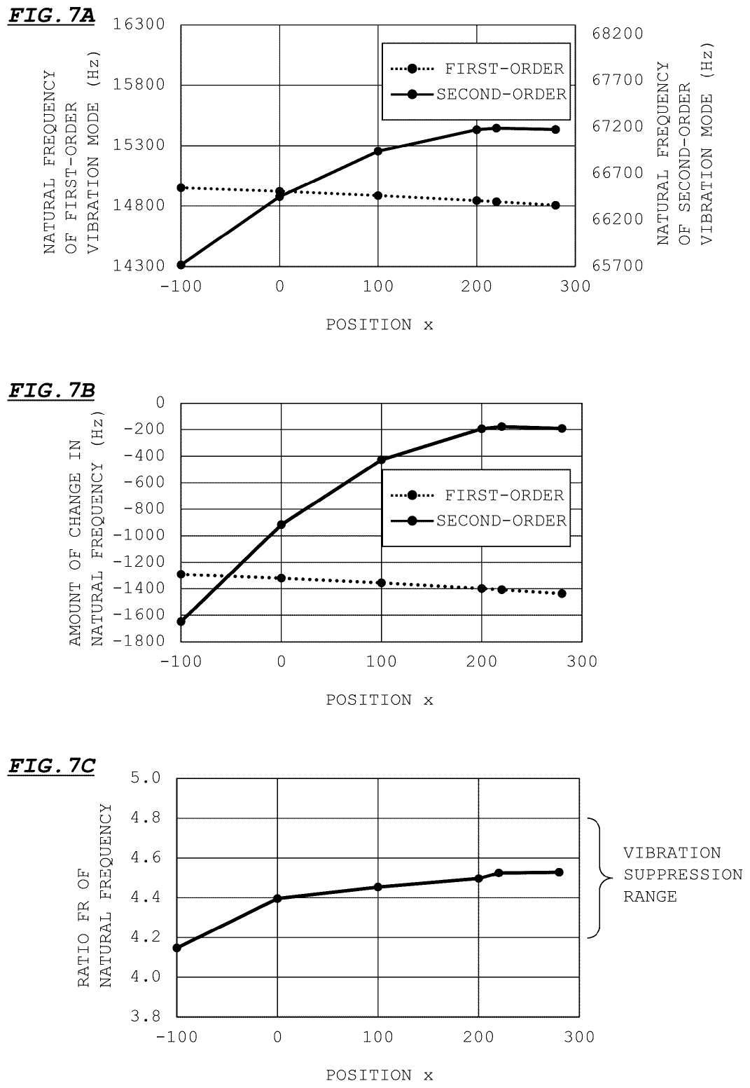

FIG. 7A to FIG. 7C are diagrams showing simulation results when the position x of each protrusion 21 or 22 was varied in the range of −100 μm to +280 μm in the configurations in FIG. 6A to FIG. 6C.

As shown in FIG. 7A and FIG. 7B, the amount of change in the natural frequency of the first-order vibration mode almost does not change in accordance with the change of the position x of each protrusion 21 or 22. Meanwhile, the amount of change in the natural frequency of the second-order vibration mode (amount of change with respect to the target frequency) increases in the range where the position x of each protrusion 21 or 22 is small. This is because when the position x is small, the region where the protrusions 21 and 22 overlap the extension line of the node line S10 becomes small. Therefore, when adjusting the natural frequency of the first-order vibration mode without the natural frequency of the second-order vibration mode greatly deviating from the target frequency, it is preferable that the protrusions 21 and 22 overlap the extension line of the node line S10 more. Specifically, in the case of FIG. 7A and FIG. 7B, it is preferable to set the position x to about 220 μm.

In FIG. 7C as well, the ratio FR is preferably away from an integer such as 4 or 5 and is preferably a value within the vibration suppression range between 4.2 and 4.8. In this case, the ratio FR is most preferably the intermediate value between adjacent integers (in the case of FIG. 7C, about 4.5). When the ratio FR is a value within the vibration suppression range, the influence of the first-order vibration mode can be suppressed, thereby allowing the tuning-fork-type driving element 1 to operate normally.

In this case as well, when the position x of each protrusion 21 or 22 is set to 200 μm or more and the protrusions 21 and 22 are placed so as to overlap the extension line of each node line S10, even if the position x of each protrusion 21 or 22 is changed, the natural frequency of the second-order vibration mode does not deviate greatly from the target frequency. Therefore, by adjusting the natural frequency of the first-order vibration mode, the tuning-fork-type driving element 1 can be easily designed such that the ratio FR is a value away from an integer value.

When only the position x is changed as shown in FIG. 6A to FIG. 7C, the natural frequency of the first-order vibration mode does not change greatly as shown in FIG. 7A and FIG. 7B, and thus it becomes difficult to adjust the natural frequency of the first-order vibration mode. Therefore, for example, adjusting the length L1 of each protrusion 21 or 22 as shown in FIG. 4A to FIG. 5C allows the natural frequency of the first-order vibration mode to be adjusted more effectively.

### Effects of Embodiment 1

According to Embodiment 1, the following effects are achieved.

The pair of arm parts 20 aligned in the Y-axis direction each have the protrusions 21 and 22 that overlap the extension line of the node line S10 that occurs when the arm parts 20 vibrate in the second-order vibration mode.

With this configuration, the natural frequency of the first-order vibration mode can be changed by the protrusions 21 and 22 which are mass portions, and the natural frequency of the first-order vibration mode can be controlled by adjusting the masses of the protrusions 21 and 22 by the lengths, etc., of the protrusions 21 and 22. In addition, since the protrusions 21 and 22 which are mass portions are formed on the extension line of each node line S10, the influence of the masses of the protrusions 21 and 22 on the natural frequency of the second-order vibration mode can be suppressed. Therefore, the natural frequency of the first-order vibration mode can be easily adjusted to a frequency that is less likely to influence the second-order vibration mode, without making the natural frequency of the second-order vibration mode greatly different from the target frequency.

The protrusions 21 and 22 are integrally formed with each arm part 20.

With this configuration, the protrusions 21 and 22 and the arm parts 20 can be formed simultaneously in the same manufacturing process, so that the protrusions 21 and 22 can be easily formed on each arm part 20.

The protrusions 21 and 22 are provided on both the inner surface of the arm part 20 on the coupling part 32 side and the outer surface of the arm part 20 on the side opposite to the inner surface on the coupling part 32 side, respectively.

With this configuration, the natural frequency of the first-order vibration mode can be appropriately adjusted while the lengths and the widths of the respective protrusions 21 and 22 are adjusted in accordance with the respective constraints of the inner side and the outer side of each arm part 20.

Each drive part 50 has a piezoelectric thin film as a drive source.

With this configuration, each arm part 20 can be smoothly driven.

The first drive unit 1a and the second drive unit 1b each including the coupling part 32, the pair of arm parts 20, the support part 31, and the drive parts 50 are placed in orientations opposite to each other with the movable part 40 located therebetween, and the coupling parts 32 of the first drive unit 1a and the second drive unit 1b are connected to the movable part 40.

With this configuration, the movable part 40 can be stably driven with a larger torque by each drive unit supporting and driving the movable part 40.

As shown in FIG. 1, the light deflection element 2 includes the tuning-fork-type driving element 1 and the reflection surface 41 located on the movable part 40.

With this configuration, since the light deflection element 2 includes the tuning-fork-type driving element 1 configured as described above, the reflection surface 41 can be smoothly and stably vibrated in the second-order vibration mode. Therefore, light incident on the reflection surface 41 can be stably deflected as the movable part 40 vibrates.

As shown in FIG. 1, the protrusions 21 that oppose each other across the rotation axis R10 are formed symmetrically about the rotation axis R10, and the protrusions 22 that oppose each other across the rotation axis R10 are formed symmetrically about the rotation axis R10. Accordingly, the weight balance between the components on the Y-axis positive side and the components on the Y-axis negative side can be equal in the first drive unit 1a and the second drive unit 1b. Therefore, unintended influence of the protrusions 21 and 22 on the rotation of the tuning-fork-type driving element 1 can be avoided.

### Embodiment 2

In Embodiment 1, the protrusions 21 and 22, which extend perpendicularly to the arm part 20 (in the Y-axis direction), are placed so as to overlap the extension line of each node line S10. In Embodiment 2, however, protrusions 21 and 22 are placed along the extension line of each node line S10.

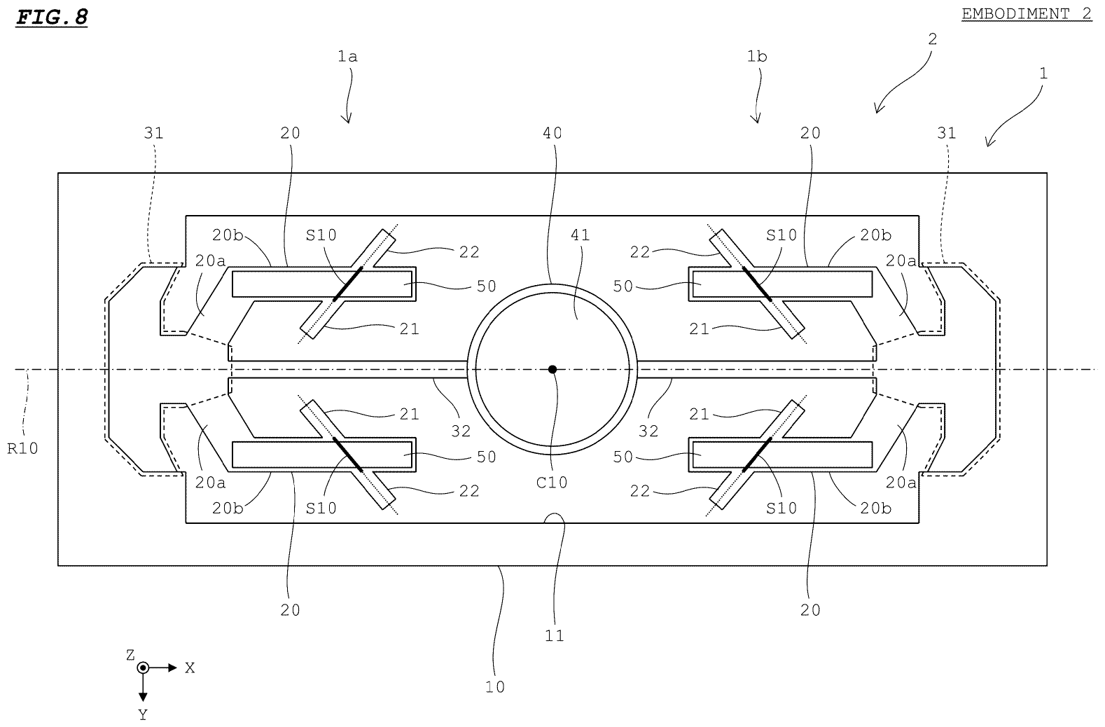

FIG. 8 is a plan view schematically showing configurations of a tuning-fork-type driving element 1 and a light deflection element 2 according to Embodiment 2.

The tuning-fork-type driving element 1 and the light deflection element 2 of Embodiment 2 are different from those of Embodiment 1 shown in FIG. 1 only in the direction in which the protrusions 21 and 22 are formed. In Embodiment 2, the protrusions 21 and 22 are formed along the extension line of each node line S10.

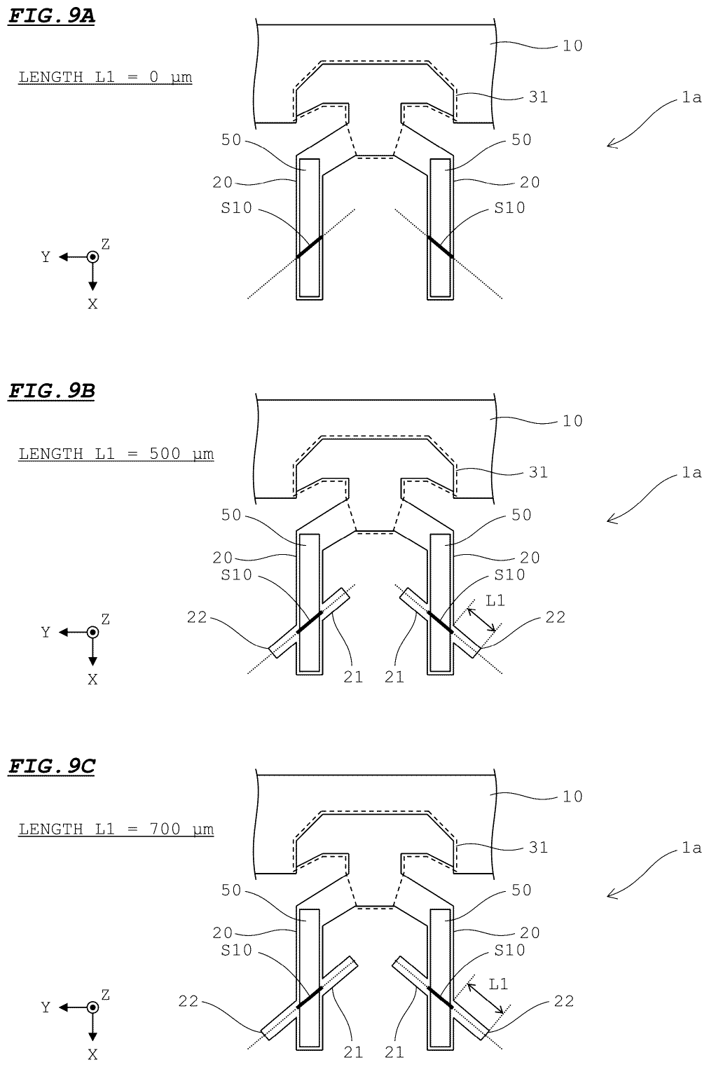

Next, an example in which the configurations of the protrusions 21 and 22 are adjusted such that the influence of the first-order vibration mode is suppressed in Embodiment 2, will be described with reference to FIG. 9A to FIG. 15C. The inventors obtained a ratio FR of the natural frequency of the second-order vibration mode to the natural frequency of the first-order vibration mode while varying the lengths and the widths of the protrusions 21 and 22 through simulation.

A tuning-fork-type driving element 1 according to simulation of Embodiment 2 described below includes a first drive unit 1a and a fixation part 10 around a support part 31 as shown in FIG. 9B, for example. In this case, the coupling part 32 is omitted from the first drive unit 1a.

FIG. 9A to FIG. 9C are each a plan view schematically showing a configuration of each arm part 20 when a length L1 of each protrusion 21 or 22 was varied, according to the simulation of Embodiment 2. FIG. 9A shows the same configuration as the comparative example shown in FIG. 3A for comparison.

FIG. 9A to FIG. 9C show states where the length L1 of each protrusion 21 or 22 was 0 μm, 500 μm, and 700 μm, respectively. The length L1 is the length of each protrusion 21 or 22 that protrudes along the extension line of the node line S10 from the arm part 20. In this simulation, the length of each protrusion 21 and the length of each protrusion 22 are both L1.

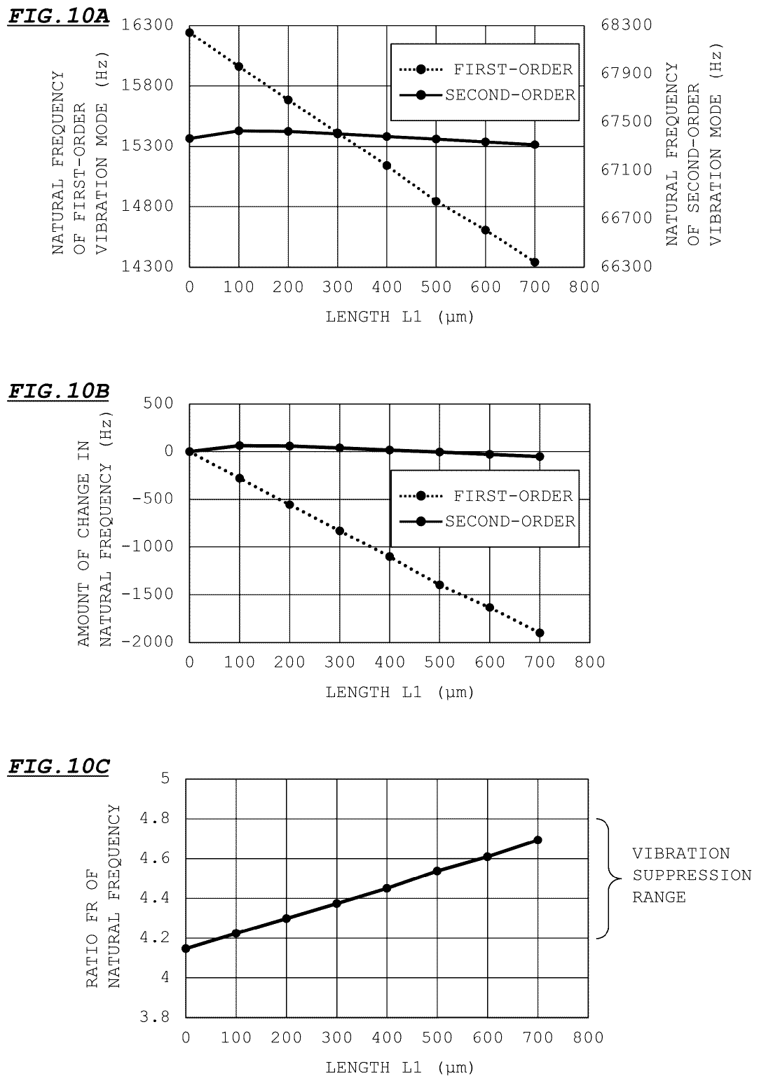

FIG. 10A to FIG. 10C are diagrams showing simulation results when the length L1 of each protrusion 21 or 22 was varied in the range of 0 μm to 700 μm in the configurations in FIG. 9A to FIG. 9C.

As shown in FIG. 10A and FIG. 10B, the amount of change in the natural frequency of the first-order vibration mode varies greatly in accordance with the change of the length L1 of each protrusion 21 or 22. Meanwhile, the amount of change in the natural frequency of the second-order vibration mode (amount of change with respect to the target frequency) almost does not change even when the length L1 of each protrusion 21 or 22 changes. The amount of change in the natural frequency of the second-order vibration mode in this case is even smaller than in FIG. 5B. This is because the protrusions 21 and 22 are placed on and along the extension line of each node line S10.

As shown in FIG. 10C, when the length L1 of each protrusion 21 or 22 changes, the ratio FR of the natural frequency also changes. In FIG. 10C as well, the ratio FR is preferably away from an integer such as 4 or 5 and is preferably a value within a vibration suppression range between 4.2 and 4.8. In this case, the ratio FR is most preferably the intermediate value between adjacent integers (in the case of FIG. 10C, about 4.5). When the ratio FR is a value within the vibration suppression range, the influence of the first-order vibration mode can be suppressed, thereby allowing the tuning-fork-type driving element 1 to operate normally.

In this case as well, even if the length L1 of each protrusion 21 or 22 is changed, the natural frequency of the second-order vibration mode does not deviate greatly from the target frequency. Therefore, by adjusting the natural frequency of the first-order vibration mode, the tuning-fork-type driving element 1 can be easily designed such that the ratio FR is a value away from an integer value. In addition, since the amount of change in the natural frequency of the second-order vibration mode is even smaller than in the case of FIG. 5B, when the natural frequency of the first-order vibration mode is adjusted, the natural frequency of the second-order vibration mode can be further inhibited from deviating from the target frequency.

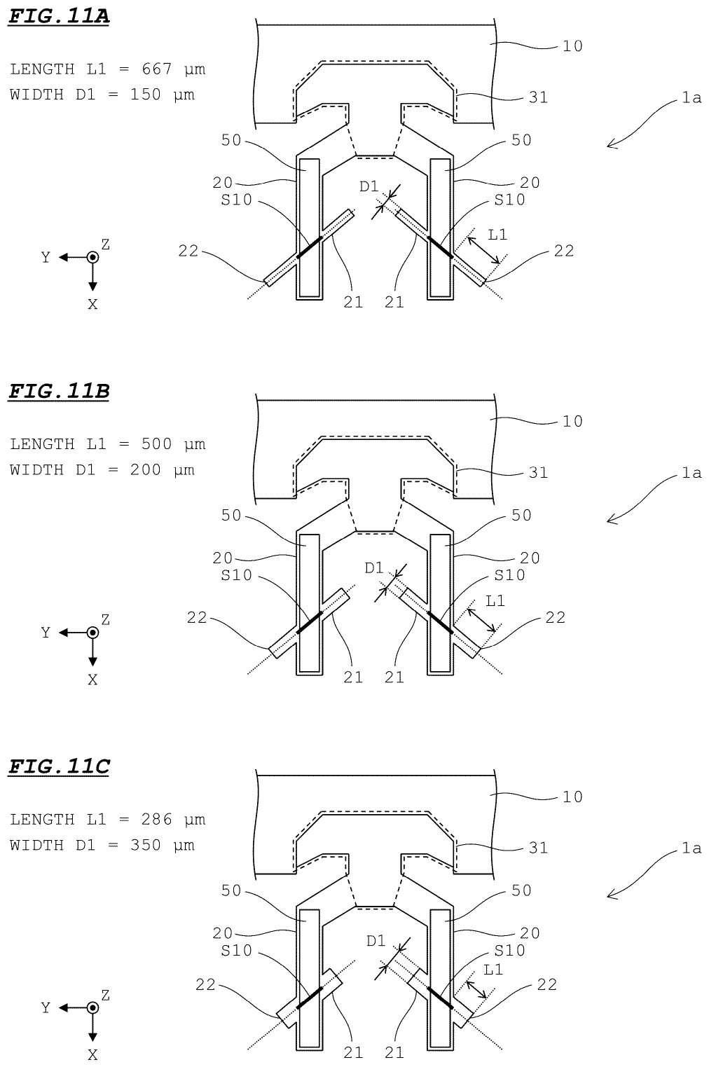

FIG. 11A to FIG. 11C are plan views schematically showing a configuration of each arm part 20 when the length L1 and a width D1 of each protrusion 21 or 22 were varied while the masses of the protrusions 21 and 22 were kept constant, according to simulation of Embodiment 2.

FIG. 11A to FIG. 11C show states where a set of the length L1 and the width D1 of each protrusion 21 or 22 was 667 μm and 150 μm, 500 μm and 200 μm, and 286 μm and 350 μm, respectively. The width D1 is the width of each protrusion 21 or 22 in a direction perpendicular to the direction of the length L1. In this simulation, the area of each projection 21 and 22 is substantially the same.

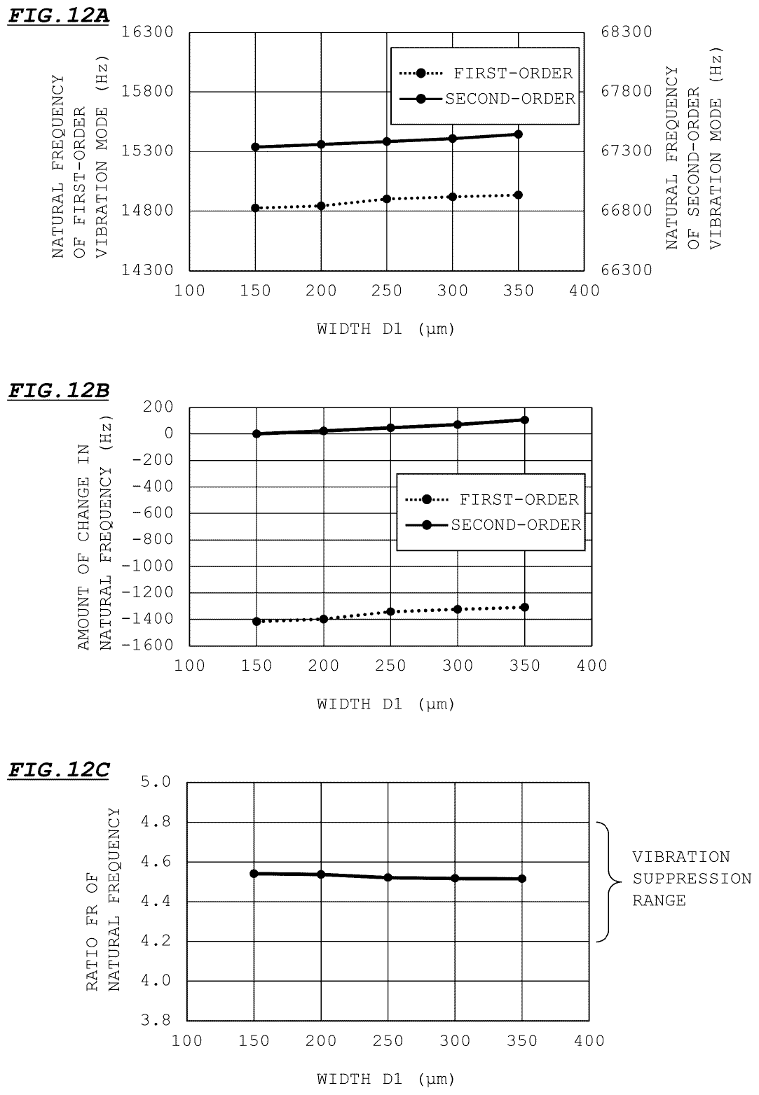

FIG. 12A to FIG. 12C are diagrams showing simulation results when the width D1 of each protrusion 21 or 22 was varied in the range of 150 μm to 350 μm in the configurations in FIG. 11A to FIG. 11C.

As shown in FIG. 12A and FIG. 12B, the amounts of change in the natural frequency of the first-order vibration mode and the natural frequency of the second-order vibration mode do not change greatly even when the width D1 of each protrusion 21 or 22 changes. However, when the width D1 increases, end portions in the width direction of the protrusions 21 and 22 are away from the extension line of each node line S10, so that the natural frequency of the second-order vibration mode changes slightly. Therefore, it is preferable that the width D1 of each protrusion 21 or 22 is smaller.

As shown in FIG. 12C, in this example, the ratio FR is constant at around 4.5 regardless of the width D1, and the ratio FR is a value within the vibration suppression range. Therefore, even if the width D1 is set to any value within the range of 150 μm to 350 μm, the influence of the first-order vibration mode can be suppressed.

According to this simulation, the ratio FR almost does not change even if the width D1 is changed under the condition of constant area as described above, so that it can be said that it is possible to change the shapes of the protrusions 21 and 22 if necessary. Accordingly, for example, when designing each arm part 20, as shown in FIG. 9A to FIG. 10C, the lengths of the protrusions 21 and 22 can be adjusted to set the natural frequency of the first-order vibration mode that is less likely to influence the second-order vibration mode, and then the length L1 and the width D1 can be freely changed while the areas of the protrusions 21 and 22 are kept constant.

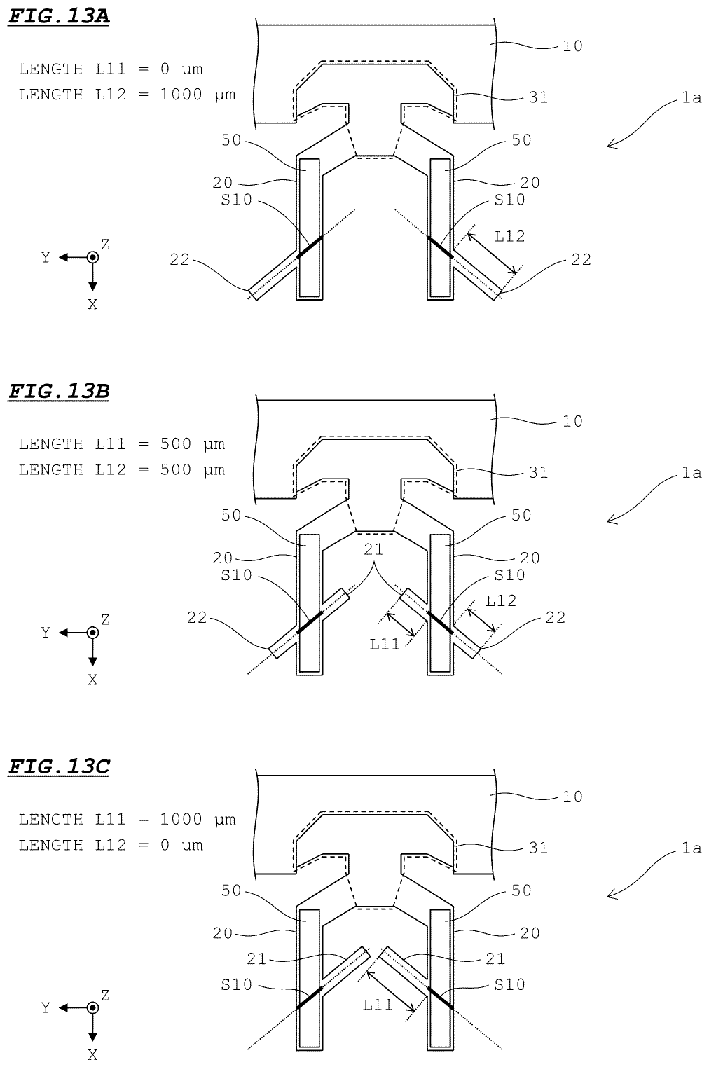

FIG. 13A to FIG. 13C are plan views schematically showing a configuration of each arm part 20 when the length of each protrusion 21 or 22 was varied while the sum of the lengths of the protrusions 21 and 22 provided on one arm part 20 was kept constant, according to simulation of Embodiment 2.

FIG. 13A to FIG. 13C show states where a set of a length L11 of each protrusion 21 and a length L12 of each protrusion 22 was 0 μm and 1000 μm, 500 μm and 500 μm, and 1000 μm and 0 μm, respectively. In this simulation, the sum of the length L11 of the protrusion 21 and the length L12 of the protrusion 22 provided on one arm part 20 is the same on both sides.

As shown in FIG. 13A, when only the outer protrusions 22 are formed, the mass of each protrusion 22 is put on a position closer to the antinode in the first-order vibration mode (near the distal end of the arm part 20) compared to the case where only the inner protrusions 21 are formed. Accordingly, the natural frequency of the first-order vibration mode can be smoothly changed by the outer protrusions 22 which are smaller than the inner protrusions 21. In addition, as shown in FIG. 13C, when only the inner protrusions 21 are formed, no protrusion protrudes on the outer side of the pair of arm parts 20. Accordingly, the width in the Y-axis direction of the opening 11 (see FIG. 8) of the fixation part 10 can be reduced, so that the outer width of the fixation part 10 can be reduced. Therefore, the outer width of the tuning-fork-type driving element 1 can be reduced.

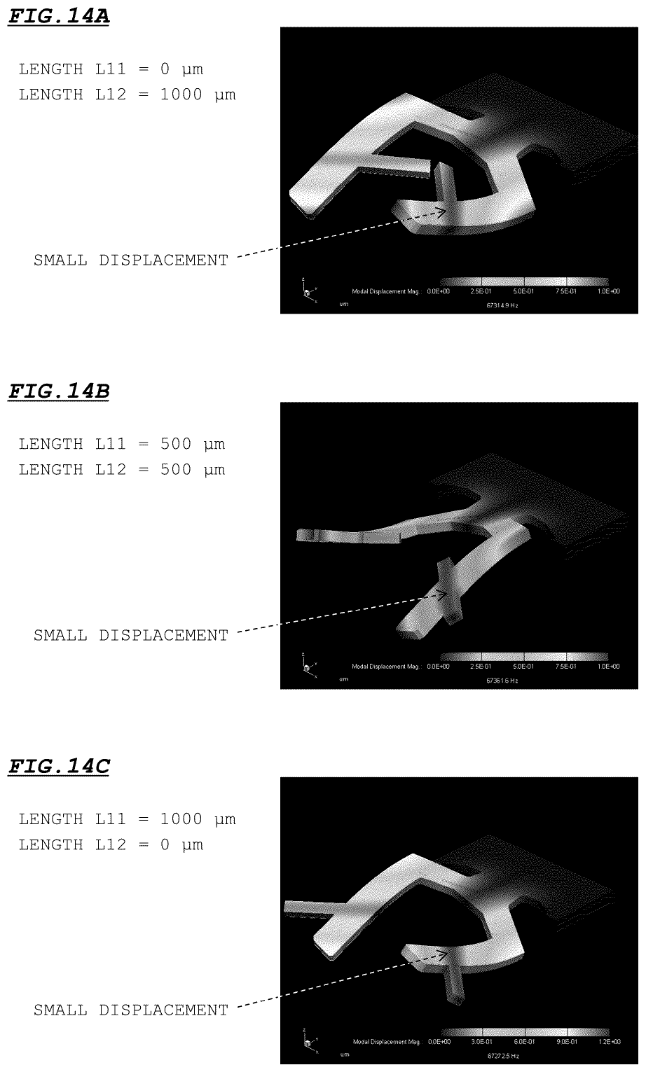

FIG. 14A to FIG. 14C are diagrams showing simulation results showing a displacement amount in the Z-axis direction when the structures in FIG. 13A to FIG. 13C were vibrated in the second-order vibration mode, respectively. The black portion of each arm part 20 indicates that the displacement amount in the Z-axis direction from a neutral position is small.

In all cases of FIG. 14A to FIG. 14C, the directions in which the protrusions 21 and 22 extend and the directions in which the portions having a small displacement amount (node lines S10) extend substantially coincide, so that it can be found that the protrusions 21 and 22 are less likely to influence the second-order vibration mode.

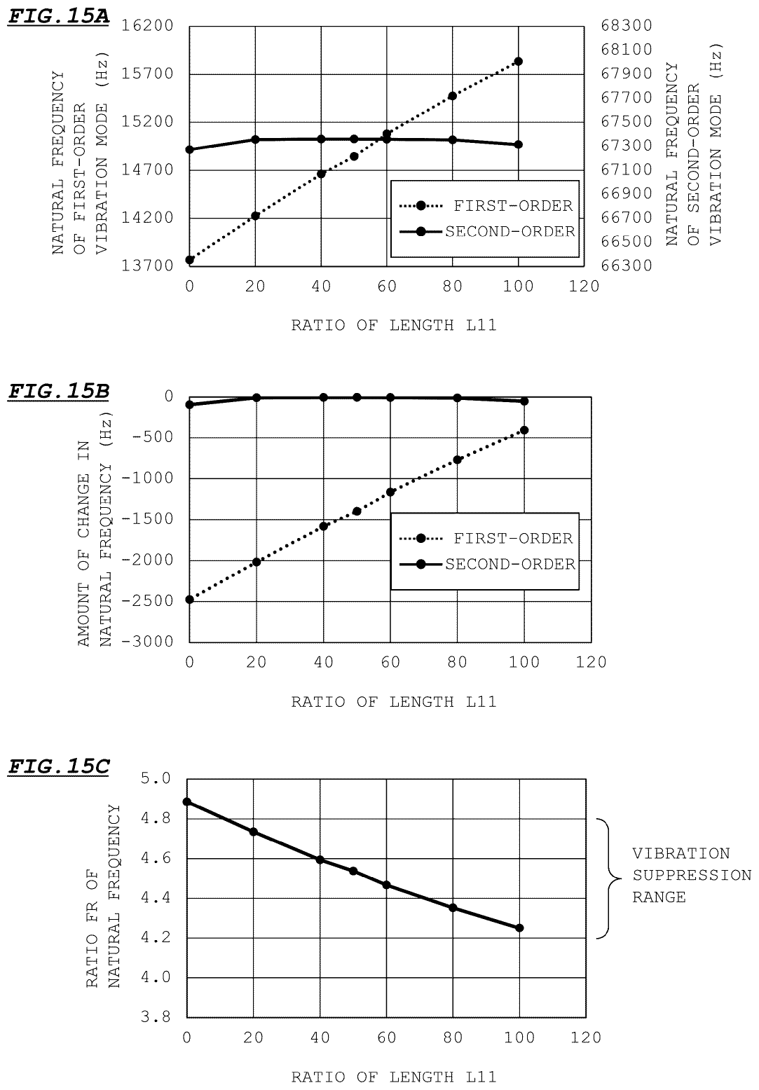

FIG. 15A to FIG. 15C are diagrams showing simulation results when the ratio of the length L11 of the protrusion 21 to the sum (L11+L12) of the lengths of the protrusions 21 and 22 was varied in the range of 0% to 100% in the configurations in FIG. 13A to FIG. 13C.

As shown in FIG. 15A and FIG. 15B, the amount of change in the natural frequency of the first-order vibration mode changes greatly in accordance with the ratio of the length L11 of the protrusion 21. Meanwhile, the amount of change in the natural frequency of the second-order vibration mode (amount of change with respect to the target frequency) almost does not change even if the ratio of the length L11 of the protrusion 21 changes. This is because the protrusions 21 and 22 are placed on and along the extension line of each node line S10.

In FIG. 15C as well, the ratio FR is preferably away from an integer such as 4 or 5 and is preferably a value within the vibration suppression range between 4.2 and 4.8. In this case, the ratio FR is most preferably the intermediate value between adjacent integers (in the case of FIG. 15C, about 4.5). When the ratio FR is a value within the vibration suppression range, the influence of the first-order vibration mode can be suppressed, thereby allowing the tuning-fork-type driving element 1 to operate normally.

If the protrusions 21 and 22 are excessively long, the vibration mode of the protrusions 21 and 22 themselves may occur, and the natural frequency of the second-order vibration mode may fluctuate. In such a case, it is preferable to adjust the lengths, the widths, the thicknesses, etc., of the protrusions 21 and 22 to suppress fluctuations in the natural frequency of the second-order vibration mode due to the protrusions 21 and 22.

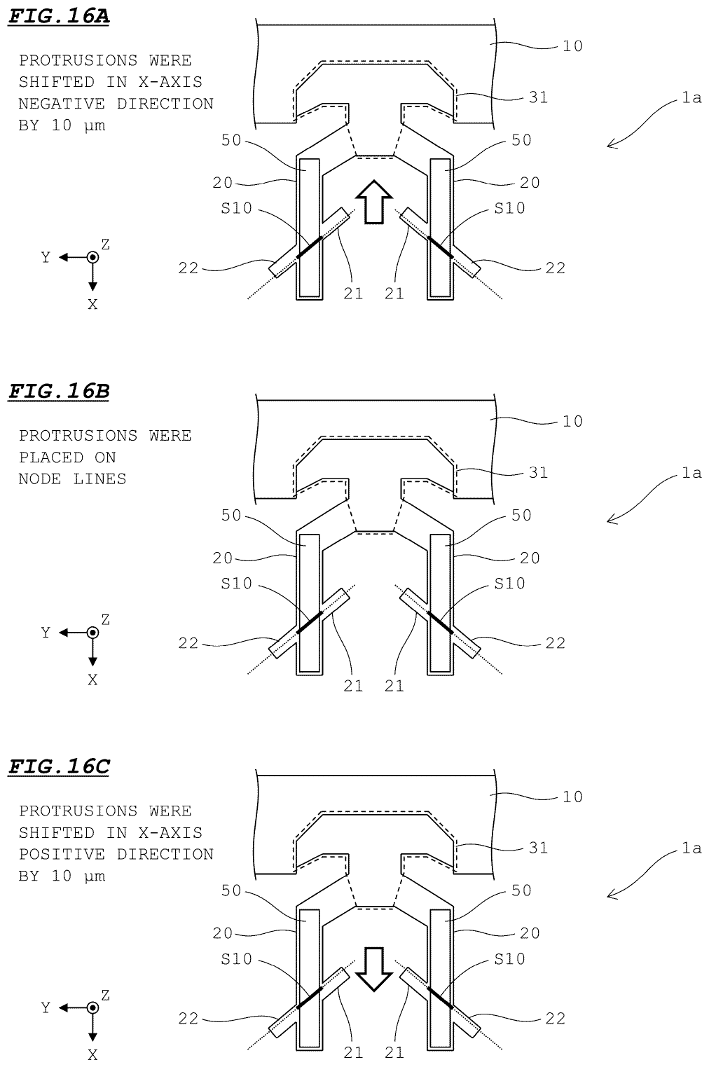

Next, a fact that it is preferable that the distal ends of the protrusions 21 and 22 are not fixed will be described with reference to FIG. 16A to FIG. 19C. The inventors obtained the displacement amount in the Z-axis direction of each arm part 20 while varying the positions in the X-axis direction of the protrusions 21 and 22 through simulation of Embodiment 2 and a comparative example.

FIG. 16A to FIG. 16C are plan views schematically showing a configuration of each arm part 20 when the positions of the protrusions 21 and 22 were shifted in the X-axis direction from a position on the extension line of the node line S10, according to simulation of Embodiment 2.

In FIG. 16B, the protrusions 21 and 22 extend on and along the extension line of each node line S10. In FIG. 16A and FIG. 16C, the protrusions 21 and 22 are shifted by 10 μm in the X-axis negative direction and the X-axis positive direction, respectively, from the state of FIG. 6B. In the simulation of Embodiment 2, the distal ends of the protrusions 21 and 22 are not fixed.

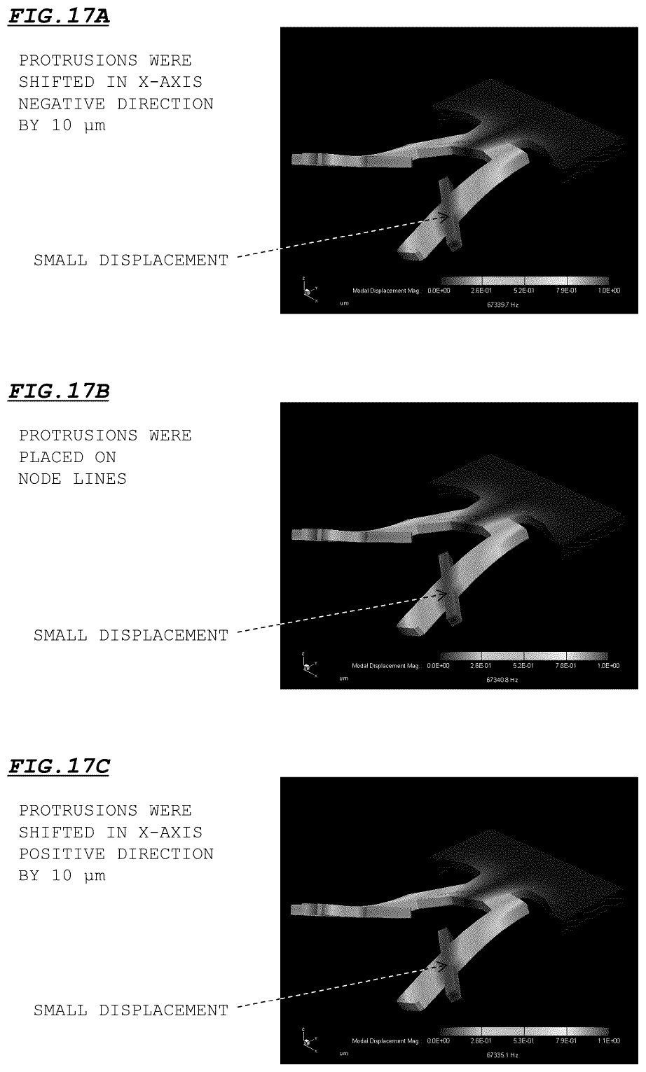

FIG. 17A to FIG. 17C are diagrams showing simulation results showing a displacement amount in the Z-axis direction when the structures in FIG. 16A to FIG. 16C were vibrated in the second-order vibration mode, respectively. The black portion of each arm part 20 indicates that the displacement amount in the Z-axis direction from a neutral position is small.

In FIG. 17A to FIG. 17C, the natural frequencies of the second-order vibration mode are 67340.8 Hz, 67339.7 Hz, and 67335.1 Hz, respectively. That is, in the cases of FIG. 17A and FIG. 17C, the deviations of the natural frequency of the second-order vibration mode are only about +1 Hz and −5 Hz, respectively, compared to FIG. 17B. From this, it can be found that, even if the protrusions 21 and 22 are unintentionally shifted by about 10 μm in the X-axis direction from the position on the extension line of the node line S10, the natural frequency of the second-order vibration mode almost does not change. Therefore, with the configurations of Embodiment 2 in FIG. 16A to FIG. 16C, the natural frequency of the second-order vibration mode does not change greatly with respect to the positional shift of the protrusions 21 and 22, so that the manufacturing variation of the tuning-fork-type driving element 1 can be suppressed.

If each arm part 20 is vibrated in the second-order vibration mode when no protrusions 21 and 22 are formed thereon, the natural frequency of the second-order vibration mode is 67366.2 Hz. From this, it can be found that, since the natural frequency of the second-order vibration mode in each of FIG. 17A to FIG. 17C almost does not change from the natural frequency of the second-order vibration mode in the case where there are no protrusions 21 and 22, the protrusions 21 and 22 have almost no influence on the second-order vibration mode.

In all cases of FIG. 17A to FIG. 17C, the directions in which the protrusions 21 and 22 extend and the directions in which the portions having a small displacement amount (node lines S10) extend substantially coincide. From this as well, it can be found that the protrusions 21 and 22 are less likely to influence the second-order vibration mode.

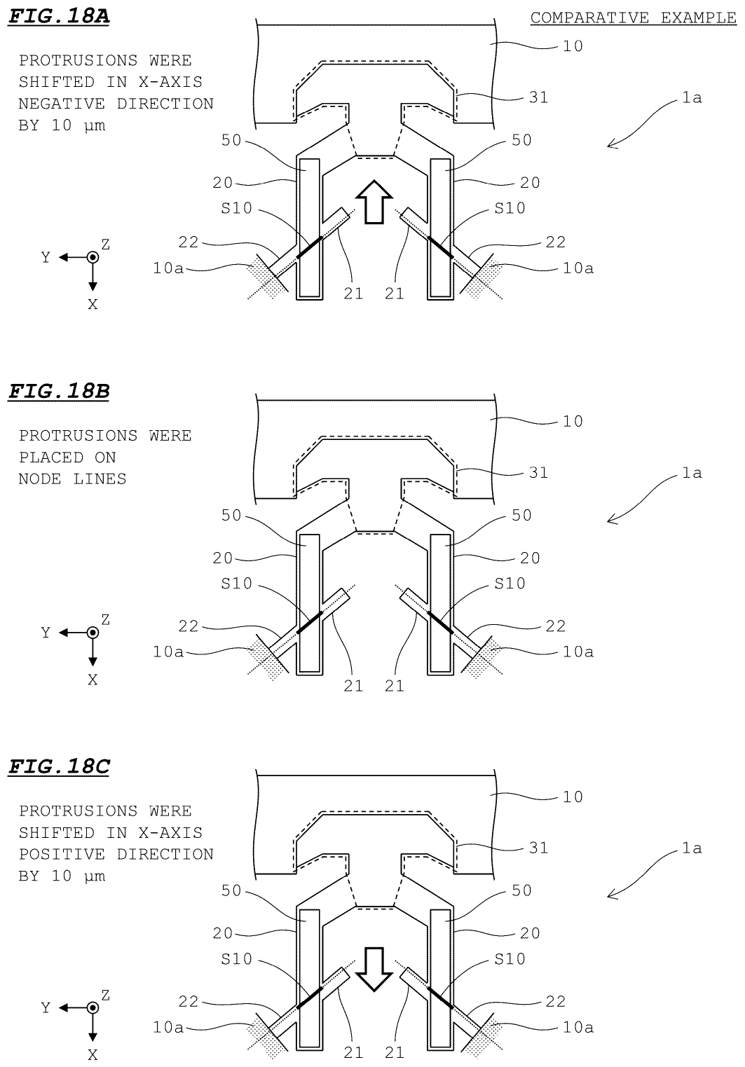

FIG. 18A to FIG. 18C are plan views schematically showing a configuration of each arm part 20 when the positions of the protrusions 21 and 22 were shifted in the X-axis direction from a position on the extension line of the node line S10, according to simulation of the comparative example.

In FIG. 18A to FIG. 18C, the positions of the protrusions 21 and 22 are the same as in FIG. 16A to FIG. 16C, respectively. However, in the simulation of the comparative example, the distal end of each protrusion 22 is fixed to a portion 10a of the fixation part 10.

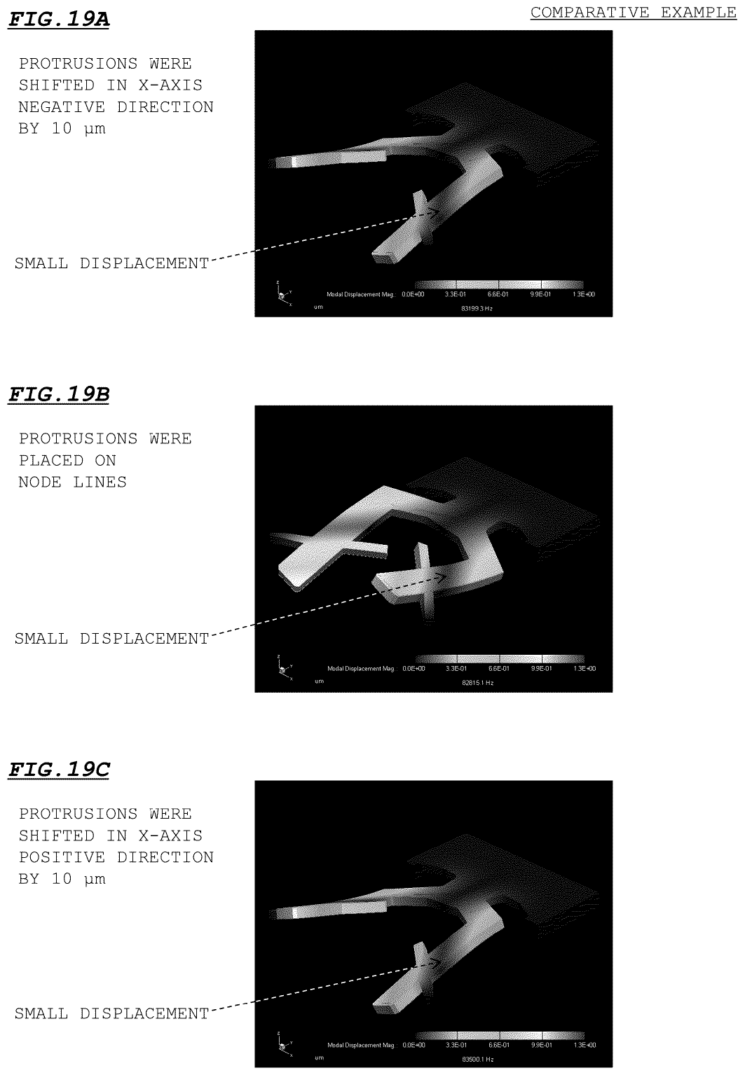

FIG. 19A to FIG. 19C are diagrams showing simulation results showing a displacement amount in the Z-axis direction when the structures in FIG. 18A to FIG. 18C were vibrated in the second-order vibration mode, respectively. The black portion of each arm part 20 indicates that the displacement amount in the Z-axis direction from a neutral position is small.

In FIG. 19A to FIG. 19C, the natural frequencies of the second-order vibration mode are 82815.1 Hz, 83119.3 Hz, and 83500.1 Hz, respectively. That is, in the cases of FIG. 19A and FIG. 19C, the deviations of the natural frequency of the second-order vibration mode are about +384 Hz and −300 Hz, respectively, which are larger than in FIG. 19B. From this, it can be found that in the comparative example, if the protrusions 21 and 22 are unintentionally shifted by about 10 μm in the X-axis direction from the position on the extension line of the node line S10, the natural frequency of the second-order vibration mode changes greatly. Therefore, in the case where the distal end of each protrusion 22 is fixed as shown in FIG. 18A to FIG. 18C, the natural frequency of the second-order vibration mode changes greatly with respect to the positional shift of the protrusions 21 and 22, so that the manufacturing variation of the tuning-fork-type driving element 1 increases.

In all cases of FIG. 19A to FIG. 19C, the directions in which the protrusions 21 and 22 extend deviate from the directions in which the portions having a small displacement amount (node lines S10) extend, so that it can be found that the protrusions 21 and 22 influence the second-order vibration mode.

### Effects of Embodiment 2

According to Embodiment 2, the following effects are achieved.

As shown in FIG. 8, the protrusions 21 and 22 are configured to vibrate together with the arm parts 20 without being restricted by another element (e.g., the fixation part 10) other than the arm parts 20. With this configuration, the protrusions 21 and 22 can move freely together with the arm parts 20, so that the protrusions 21 and 22 are less likely to influence the natural frequency of the second-order vibration mode as described with reference to FIG. 16A to FIG. 19C. Therefore, the natural frequency of the second-order vibration mode can be set appropriately to the target frequency.

The protrusions 21 and 22 extend along the extension line of each node line S10.

With this configuration, the change in the natural frequency of the second-order vibration mode due to the protrusions 21 and 22 can be suppressed compared to the case where the protrusions 21 and 22 extend non-parallel to each node line S10. Therefore, the natural frequency of the second-order vibration mode can be set more appropriately to the target frequency.

As shown in FIG. 13C, the protrusion 21 may be provided only on the inner surface of each arm part 20 on the coupling part 32 side.

With this configuration, since no protrusion protrudes on the outer side of each arm part 20, the outer width of the tuning-fork-type driving element 1 can be reduced.

### Modifications of Protrusions

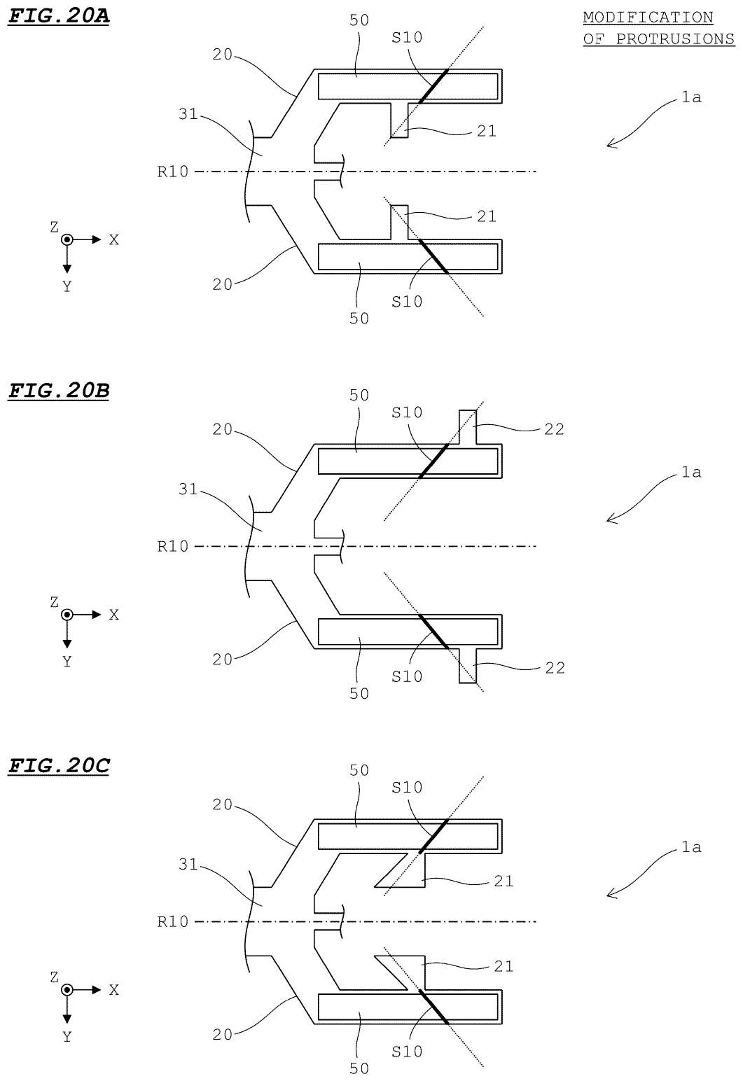

The shapes of the protrusions 21 and 22 are not limited to those shown in Embodiments 1 and 2, as long as the protrusions 21 and 22 are placed so as to overlap the extension line of each node line S10 in a plan view. The protrusions 21 and 22 may be configured as shown in FIG. 20A to FIG. 22B, for example. In the following modifications as well, protrusions respectively formed on the pair of arm parts 20 aligned in Y-axis direction are configured to be line-symmetrical about the rotation axis R10.

As shown in FIG. 20A, only the inner protrusion 21 may be formed on each arm part 20. In addition, each protrusion 21 in FIG. 20A may be formed on and along the extension line of the node line S10, similar to each protrusion 21 of Embodiment 2.

As shown in FIG. 20B, only the outer protrusion 22 may be formed on each arm part 20. In addition, each protrusion 22 in FIG. 20B may be formed on and along the extension line of the node line S10, similar to each protrusion 22 of Embodiment 2.

As shown in FIG. 20C, each inner protrusion 21 may be formed so as to become wider as the distance from the connected arm part 20 increases. In addition, each outer protrusion 22 may be formed so as to become wider as the distance from the connected arm part 20 increases. If the protrusions 21 and 22 are each configured such that the width at the base thereof is different from the width at the distal end thereof as described above, when forming the protrusions 21 and 22 having masses required for adjusting the natural frequency of the first-order vibration mode, by making the width at the base and the width at the distal end of each protrusion 21 or 22 different from each other, it is possible to adjust the shapes of the protrusions 21 and 22 to shapes corresponding to each requirement, such as being able to easily adjust the length of each protrusion 21 or 22 to the target length or being able to form each protrusion 21 or 22 in a shape that can suppress the influence on the natural frequency of the second-order vibration mode.

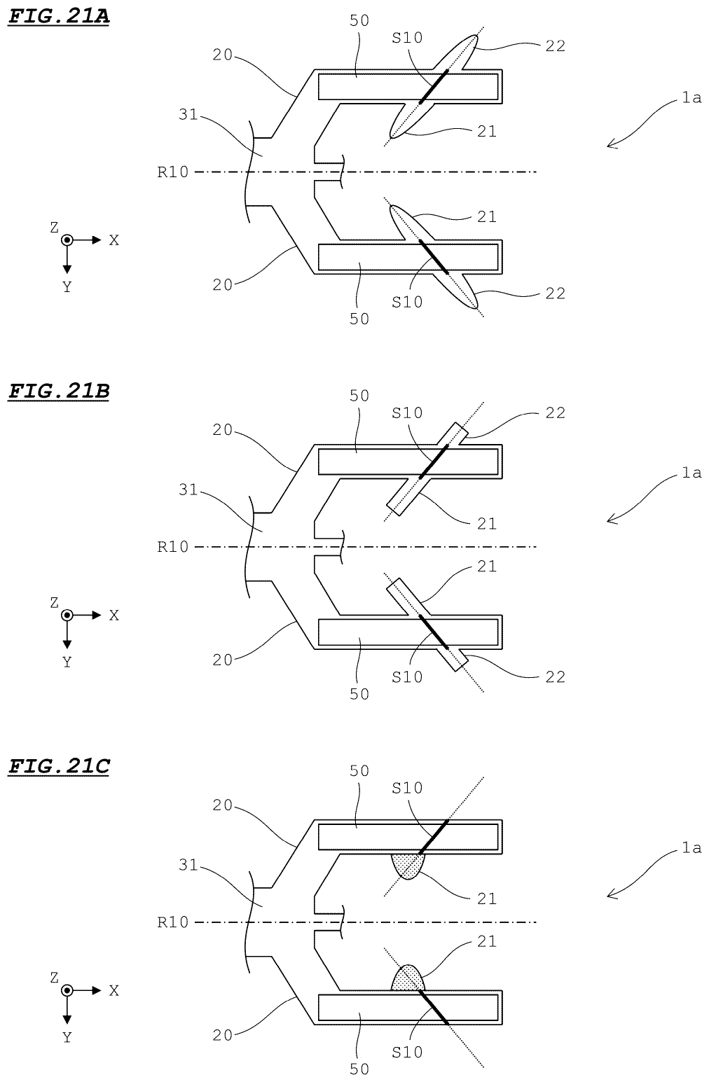

As shown in FIG. 21A, the protrusions 21 and 22 may each be formed so as to become narrower as the distance from the connected arm part 20 increases. In this case, since the distal ends of the protrusions 21 and 22 are narrow, the natural frequencies of the protrusions 21 and 22 become higher, so that unnecessary vibration based on the protrusions 21 and 22 can be suppressed. In addition, in this case as well, since the protrusions 21 and 22 are each configured such that the width at the base thereof is different from the width at the distal end thereof, the same effects as those described with reference to FIG. 20C are achieved. In FIG. 21A, either the protrusions 21 or the protrusions 22 may be omitted.

As shown in FIG. 21B, the lengths of the protrusions 21 and 22 formed on one arm part 20 may be different from each other. The length of the protrusion 21 may be longer than the length of the protrusion 22 or may be shorter than the length of the protrusion 22.

As shown in FIG. 21C, each protrusion 21 may be made of a material different from that of each arm part 20. In addition, each protrusion 22 may be made of a material different from that of each arm part 20. In the case where the protrusions 21 and 22 are each made of a material different from that of each arm part 20, the protrusions 21 and 22 may be made of a resin, for example.

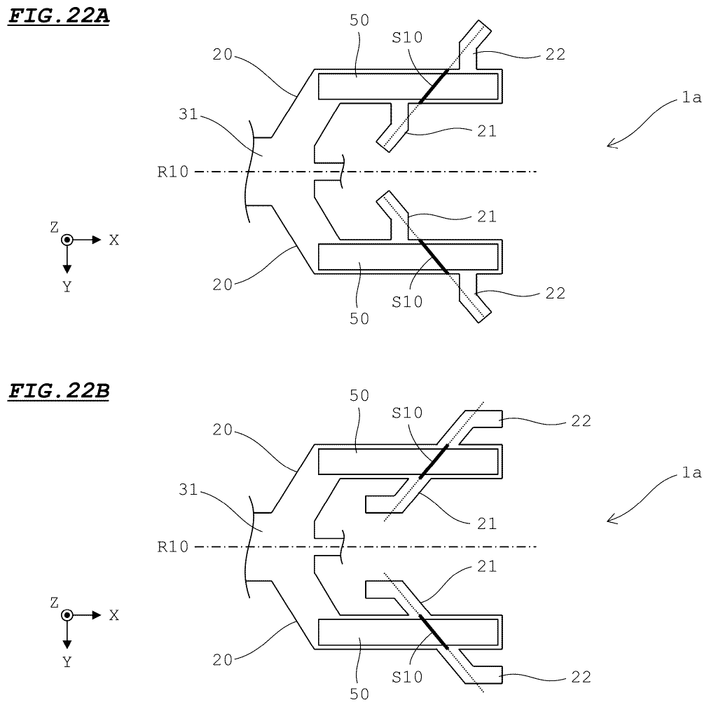

As shown in FIG. 22A, the bases of the protrusions 21 and 22 may extend in a direction perpendicular to each arm part 20 (in the Y-axis direction), and the distal ends of the protrusions 21 and 22 may extend along the extension line of each node line S10.

As shown in FIG. 22B, the bases of the protrusions 21 and 22 may extend along the extension line of each node line S10, and the distal ends of the protrusions 21 and 22 may extend in the X-axis direction. In addition, in FIG. 22B, the distal ends of the protrusions 21 and 22 may extend in the Y-axis direction.

In all the modifications in FIG. 20A to FIG. 22B, the protrusions 21 and 22 overlap the extension line of each node line S10. Accordingly, as in Embodiments 1 and 2, by adjusting the shapes, etc., of the protrusions 21 and 22, the natural frequency of the first-order vibration mode can be easily adjusted to a frequency that is less likely to influence the second-order vibration mode.

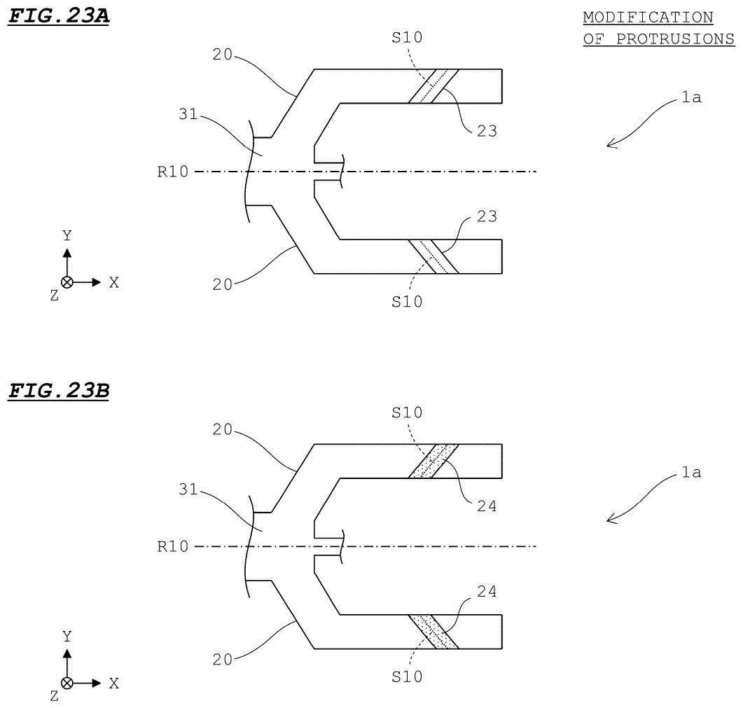

In addition, as shown in FIG. 23A, a protrusion 23 may be placed so as to overlap each node line S10 in a plan view. In this case, for example, the protrusion 23 is formed on the lower surface of the arm part 20 corresponding to the position of the node line S10. The protrusion 23 may be integrally formed with the arm part 20 using the same material (silicon) as the arm part 20 or may be formed using a different material (for example, a resin material) from that of the arm part 20.

In the example of FIG. 23A, the protrusion 23 is placed so as to protrude downward from the lower surface of each arm part 20, but a protrusion 23 may be formed on the upper surface of each arm part 20, that is, at a position, overlapping each node line S10, on the upper surface of each drive part 50, so as to protrude upward. In this case, the protrusion 23 is formed, for example, by superimposing a resin material or the like on the upper surface of the drive part 50.

In the case where a structure for adjusting the mass is placed at the position overlapping each node line S10 as described above, a recess 24 may be provided at a position, overlapping each node line S10, on the lower surface of each arm part 20 as shown in FIG. 23B, instead of the protrusion 23. The recess 24 may have a shape having walls parallel to the Z axis and having a constant depth or may have a shape that has a lowest portion at the position of the node line S10 and that gradually becomes shallower as the distance from the node line S10 increases. In the example of FIG. 23A, the width in the X-axis direction of the recess 24 is constant, and the node line S10 is positioned at the middle of this width.

The recess 24 may be provided at a position, overlapping the node line S10, on the upper surface of each arm part 20. However, since the drive part 50 is placed on the upper surface of each arm part 20, it is necessary to partially remove the drive part 50 in order to provide the recess 24. Therefore, in order to maintain the driving efficiency by the drive part 50, it is preferable to provide a recess at a position, corresponding to the node line S10, on the lower surface of each arm part 20.

Each of the protrusions 23 and the recesses 24 does not necessarily have to be located over the entire length of the node line S10 and may be located in the range of a part of the node line S10. In addition, the protrusions 23 or the recesses 24 may be provided together with the protrusions 21 and 22 described above.

### Modification of Higher-Order Vibration Mode

In Embodiments 1 and 2, each arm part 20 is driven in the second-order vibration mode, but each arm part 20 may be driven in a higher-order vibration mode higher than the second-order vibration mode.

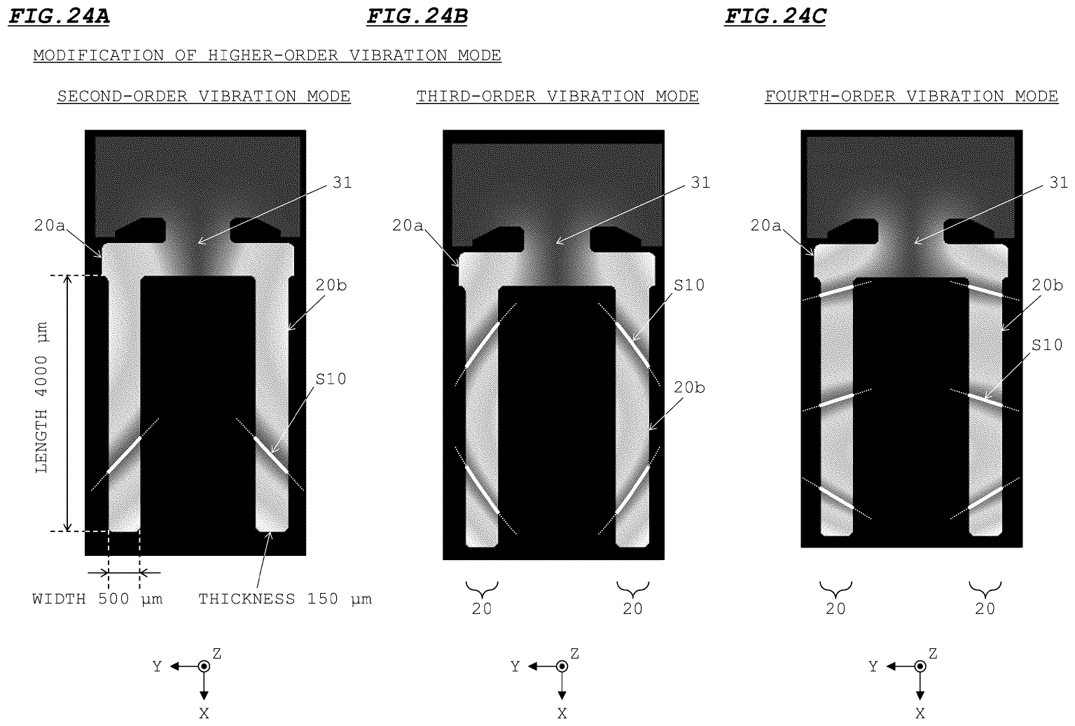

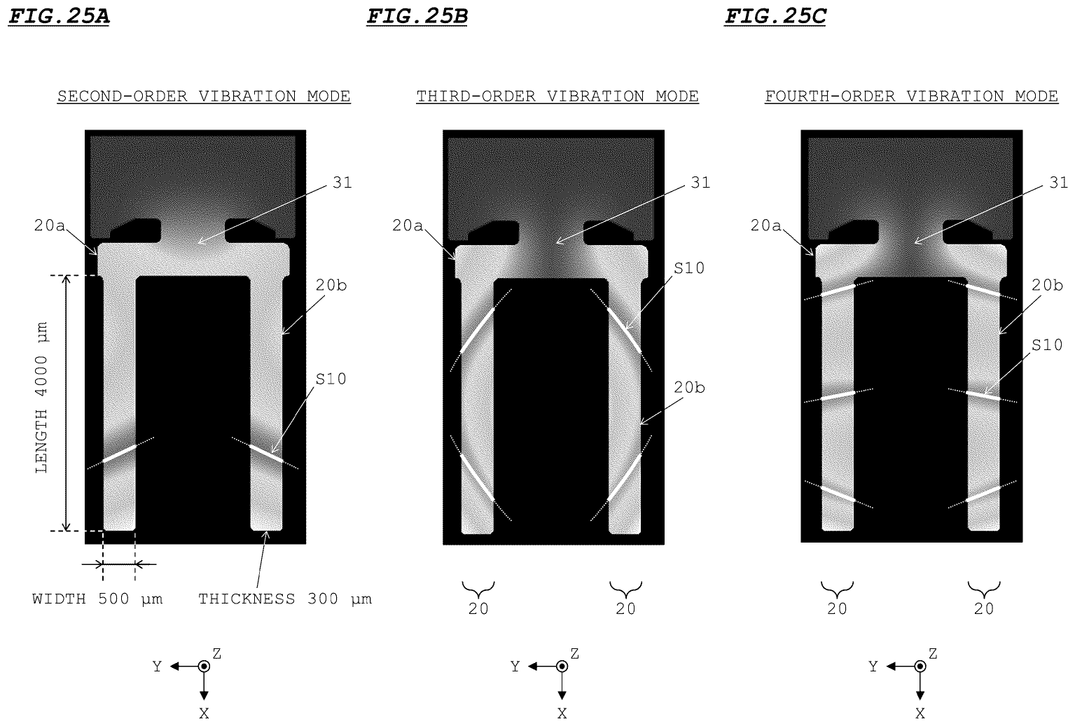

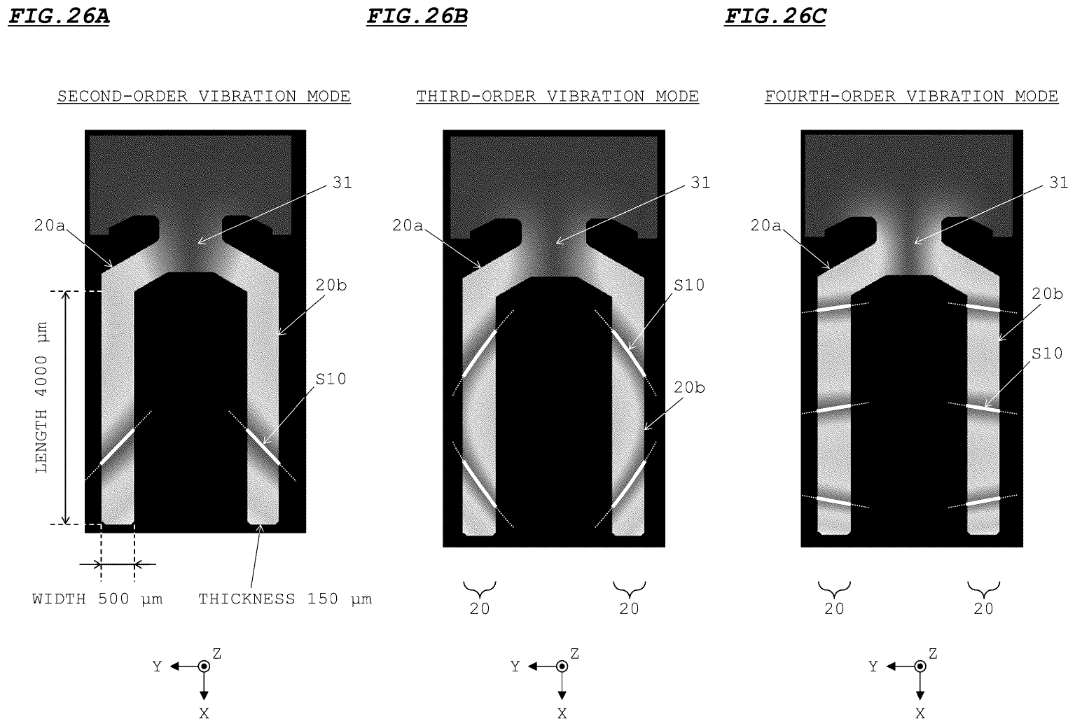

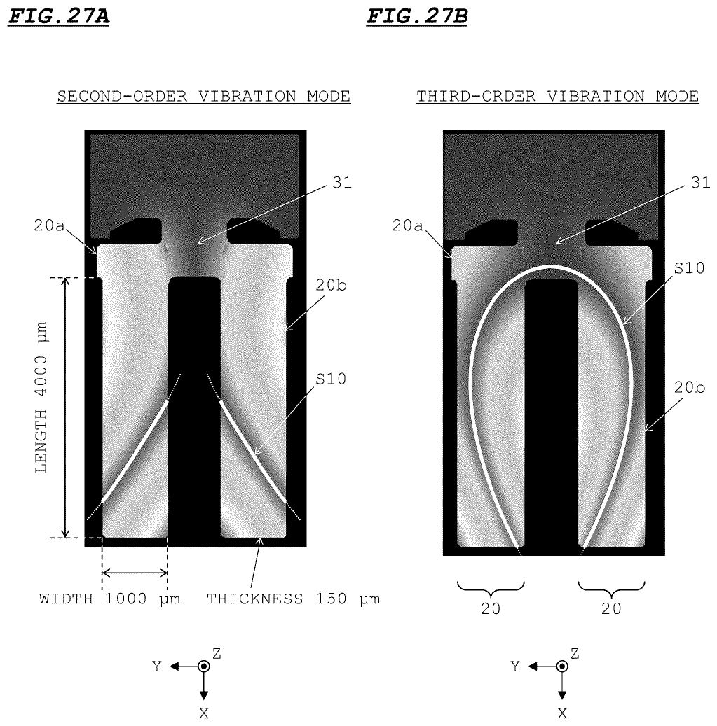

Through simulation, the inventors configured four types of first drive units 1a as shown in FIG. 24A, FIG. 25A, FIG. 26A, and FIG. 27A, and obtained the displacement amount in the Z-axis direction when each arm part 20 was driven in the higher-order vibration mode higher than the first-order vibration mode in each configuration.

FIG. 24A to FIG. 24C show simulation results showing a displacement amount in the Z-axis direction when each arm part 20 was vibrated in the second-order vibration mode, the third-order vibration mode, and the fourth-order vibration mode, respectively, in the first drive unit 1a with sizes shown in FIG. 24A.

In the first drive unit 1a in this case, the length and the width of the second portion 20b of each arm part 20 were set to 4000 μm and 500 μm, respectively, and the thickness in the Z-axis direction of each arm part 20 was set to 150 μm. The first portion 20a of each arm part 20 was formed so as to extend in the Y-axis direction. In this case, the coupling part 32 is omitted from the first drive unit 1a. In FIG. 24A to FIG. 24C, the black portion of each arm part 20 indicates that the displacement amount in the Z-axis direction from a neutral position is small.

As shown in FIG. 24A, when each arm part 20 is driven in the second-order vibration mode, a node line S10 is formed in an oblique direction with respect to one second portion 20b, as also shown in FIG. 1 and FIG. 8. In this case, as shown in Embodiments 1 and 2 and the modifications, protrusions 21 and 22 are placed so as to overlap an extension line of each node line S10 shown by a dotted line, in a plan view. By adjusting the lengths, the widths, the thicknesses, etc., of the protrusion 21 and 22, the natural frequency of the first-order vibration mode can be easily adjusted to a frequency that is less likely to influence the second-order vibration mode, without making the natural frequency of the second-order vibration mode greatly different from the target frequency.

As shown in FIG. 24B, when each arm part 20 is driven in the third-order vibration mode, two node lines S10 are formed in one second portion 20b. In this case as well, protrusions 21 and 22 are placed so as to overlap an extension line of each node line S10 shown by a dotted line, in a plan view. By adjusting the lengths, the widths, the thicknesses, etc., of the protrusion 21 and 22, the natural frequency of a lower-order vibration mode can be easily adjusted to a frequency that is less likely to influence the third-order vibration mode, without making the natural frequency of the third-order vibration mode greatly different from the target frequency.

Specifically, a ratio FR1 of the natural frequency of the third-order vibration mode to the natural frequency of the first-order vibration mode and a ratio FR2 of the natural frequency of the third-order vibration mode to the natural frequency of the second-order vibration mode are each set to a value away from an integer. In this case, it is particularly preferable to preferentially set the ratio FR1 to a value away from an integer.

As shown in FIG. 24C, when each arm part 20 is driven in the fourth-order vibration mode, three node lines S10 are formed in one second portion 20b. In this case as well, protrusions 21 and 22 are placed so as to overlap an extension line of each node line S10 shown by a dotted line, in a plan view. By adjusting the lengths, the widths, the thicknesses, etc., of the protrusion 21 and 22, the natural frequency of a lower-order vibration mode can be easily adjusted to a frequency that is less likely to influence the fourth-order vibration mode, without making the natural frequency of the fourth-order vibration mode greatly different from the target frequency.

Specifically, a ratio FR1 of the natural frequency of the fourth-order vibration mode to the natural frequency of the first-order vibration mode, a ratio FR2 of the natural frequency of the fourth-order vibration mode to the natural frequency of the second-order vibration mode, and a ratio FR3 of the natural frequency of the fourth-order vibration mode to the natural frequency of the third-order vibration mode are each set to a value away from an integer. In this case as well, it is particularly preferable to preferentially set the ratio FR1 to a value away from an integer.

FIG. 25A to FIG. 25C show simulation results showing a displacement amount in the Z-axis direction when each arm part 20 was vibrated in the second-order vibration mode, the third-order vibration mode, and the fourth-order vibration mode, respectively, in the first drive unit 1a with sizes shown in FIG. 25A.

In the first drive unit 1a in this case, the length and the width of the second portion 20b of each arm part 20 were set to 4000 μm and 500 μm, respectively, and the thickness in the Z-axis direction of each arm part 20 was set to 300 μm. The first portion 20a of each arm part 20 was formed so as to extend in the Y-axis direction.

In FIG. 25A to FIG. 25C as well, node lines S10 are formed as in FIG. 24A to FIG. 24C, although the directions and the positions of the node lines S10 are slightly different from those in FIG. 24A to FIG. 24C. In this case as well, by the protrusions 21 and 22, the natural frequency of a lower-order vibration mode can be easily adjusted to a frequency that is less likely to influence a higher-order vibration mode, without making the natural frequency of the higher-order vibration mode greatly different from the target frequency.

FIG. 26A to FIG. 26C show simulation results showing a displacement amount in the Z-axis direction when each arm part 20 was vibrated in the second-order vibration mode, the third-order vibration mode, and the fourth-order vibration mode, respectively, in the first drive unit 1a with sizes shown in FIG. 26A.

Each size of the first drive unit 1a in this case was the same as in FIG. 24A. In addition, the first portion 20a of each arm part 20 was formed so as to extend such that the first portion 20a was inclined with respect to the Y-axis direction.

In FIG. 26A to FIG. 26C as well, node lines S10 are formed as in FIG. 24A to FIG. 25C, although the directions and the positions of the node lines S10 are slightly different from those in FIG. 24A to FIG. 25C. In this case as well, by the protrusions 21 and 22, the natural frequency of a lower-order vibration mode can be easily adjusted to a frequency that is less likely to influence a higher-order vibration mode, without making the natural frequency of the higher-order vibration mode greatly different from the target frequency.

FIG. 27A and FIG. 27B show simulation results showing a displacement amount in the Z-axis direction when each arm part 20 was vibrated in the second-order vibration mode and the third-order vibration mode, respectively, in the first drive unit 1a with sizes shown in FIG. 27A.

In the first drive unit 1a in this case, the length and the width of the second portion 20b of each arm part 20 were set to 4000 μm and 1000 μm, respectively, and the thickness in the Z-axis direction of each arm part 20 was set to 150 μm. The first portion 20a of each arm part 20 was formed so as to extend in the Y-axis direction.

In FIG. 27A as well, node lines S10 are formed as in FIG. 24A, FIG. 25A, and FIG. 26A, although the directions and the positions of the node lines S10 are slightly different from those in FIG. 24A, FIG. 25A, and FIG. 26A. In this case as well, by the protrusions 21 and 22, the natural frequency of the first-order vibration mode can be easily adjusted to a frequency that is less likely to influence the second-order vibration mode, without making the natural frequency of the second-order vibration mode greatly different from the target frequency.

In FIG. 27B, a node line S10 having a substantially U-shape is formed on and along the pair of arm parts 20, which are aligned in the Y-axis direction, and the support part 31. In this case, a protrusion is placed so as to overlap an extension line of a node line S10 shown by a dotted line, from an end portion in the X-axis positive side of each arm part 20, in a plan view. By adjusting the length, width, thickness, etc., of this protrusion, the natural frequency of a lower-order vibration mode can be easily adjusted to a frequency that is less likely to influence the third-order vibration mode, without making the natural frequency of the third-order vibration mode greatly different from the target frequency.

As shown in FIG. 24B, FIG. 24C, FIG. 25B, FIG. 25C, FIG. 26B, FIG. 26C, and FIG. 27B, even when each arm part 20 is also driven in a higher-order vibration mode higher than the second-order vibration mode, it is preferable that each protrusion placed on each arm part 20 is placed so as to overlap the node line S10 or the extension line of the node line S10, and more specifically, it is preferable that the protrusion extends on and along the extension line of the node line S10. In addition, the shape of each protrusion placed on each arm part 20 is preferably configured such that the protrusion vibrates together with the arm part 20 without being restricted by another element (e.g., the fixation part 10) other than the arm part 20.

### Other Modifications

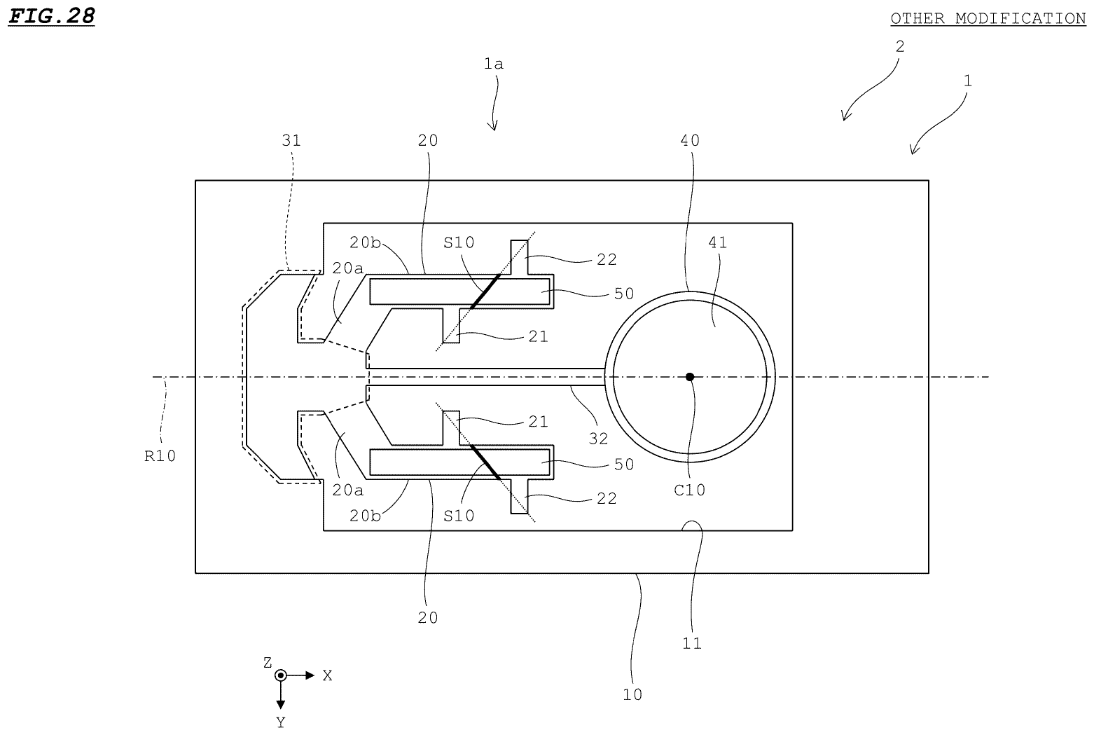

In the above embodiments and modifications, as shown in FIG. 1 and FIG. 8, the first drive unit 1a and the second drive unit 1b are placed with the movable part 40 located therebetween, but any one of the two drive units may be omitted. For example, as shown in FIG. 28, compared to Embodiment 1 shown in FIG. 1, the second drive unit 1b may be omitted, and the movable part 40 may be supported by the coupling part 32 of the first drive unit 1a. In addition, in the tuning-fork-type driving element 1 in FIG. 8, the second drive unit 1b may be omitted.

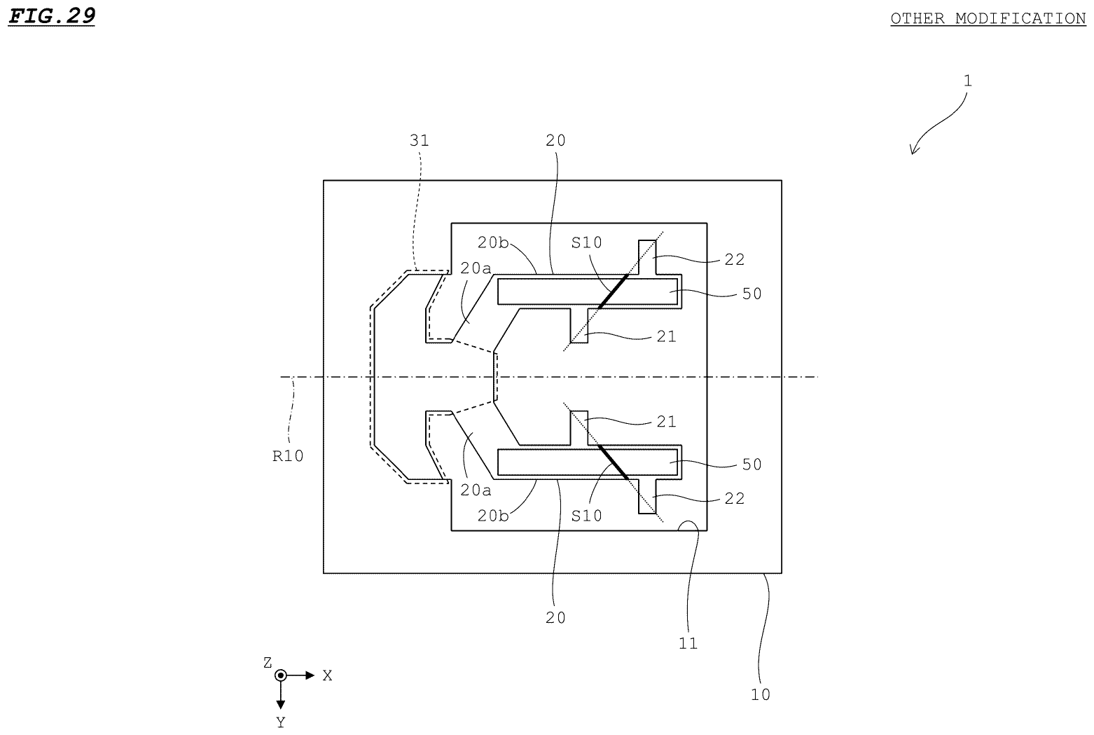

In addition, as shown in FIG. 29, the movable part 40 and the coupling parts 32 may be omitted from the tuning-fork-type driving element 1. In this case, in the configuration of FIG. 29, protrusions 21 and 22 that overlap extension lines of node lines S10 that occur in the pair of arm parts 20 when the arm parts 20 vibrate in a higher-order vibration mode higher than in the first-order vibration mode, are placed on the pair of arm parts 20. The protrusions 21 and 22 can be configured in the same manner as in the above embodiments and modifications.

In the configuration of FIG. 29 as well, instead of or in addition to the protrusions 21 and 22, a protrusion 23 that overlaps each node line S10 as shown in FIG. 23A may be placed, or a recess 24 that overlaps each node line S10 as shown in 23B may be provided. The protrusion 23 and the recess 24 can be formed by the same methods as in FIG. 23A and FIG. 23B. In addition, as in FIG. 23A and FIG. 23B, the protrusion 23 and the recess 24 may be formed on the upper surface side of each arm part 20.

Such a tuning-fork-type driving element 1 can be used as an angular velocity sensor, for example. The angular velocity of each arm part 20 rotating about the rotation axis R10 is detected based on a signal outputted from each drive part 50.

In addition to the above, various modifications can be made as appropriate to the embodiments of the present invention without departing from the scope of the technical idea defined by the claims.

### Additional Note

The following technologies are disclosed by the description of the above embodiments.

### Technology 1

A tuning-fork-type driving element including:
a movable part rotatable about a rotation axis;
a coupling part extending from the movable part along the rotation axis;
a pair of arm parts placed with the coupling part located therebetween;
a support part coupling the coupling part and the pair of arm parts to a fixation part; and
drive parts placed on the arm parts, respectively, wherein
the pair of arm parts each have a protrusion that overlaps a node line that occurs when the arm parts vibrate in a higher-order vibration mode higher than a first-order vibration mode or an extension line of the node line.

According to this technology, the natural frequency of a lower-order vibration mode can be changed by the protrusion which is a mass portion, and the natural frequency of the lower-order vibration mode can be controlled by adjusting the mass of the protrusion by the length, etc., of the protrusion. In addition, since the protrusion which is a mass portion is formed on the node line or the extension line of the node line, the influence of the mass of the protrusion on the natural frequency of the higher-order vibration mode can be suppressed. Therefore, the natural frequency of the lower-order vibration mode lower than the higher-order vibration mode can be easily adjusted to a frequency that is less likely to influence the higher-order vibration mode, without making the natural frequency of the higher-order vibration mode greatly different from the target frequency.

### Technology 2

The tuning-fork-type driving element according to technology 1, wherein the protrusion is configured to vibrate together with the arm part without being restricted by another element other than the arm part.

According to this technology, the protrusion can freely move together with the arm part, so that the protrusion is less likely to influence the natural frequency of the higher-order vibration mode. Therefore, the natural frequency of the higher-order vibration mode can be set appropriately to the target frequency.

### Technology 3

The tuning-fork-type driving element according to technology 1 or 2, wherein the protrusion extends along the extension line of the node line.

According to this technology, the change in the natural frequency of the higher-order vibration mode due to the protrusion can be suppressed compared to the case where the protrusion extends non-parallel to the node line. Therefore, the natural frequency of the higher-order vibration mode can be set more appropriately to the target frequency.

### Technology 4

The tuning-fork-type driving element according to any one of technologies 1 to 3, wherein the protrusion has a width at a base thereof different from a width at a distal end thereof.

According to this technology, when forming the protrusion having a mass required for adjusting the natural frequency of the lower-order vibration mode, by making the width at the base and the width at the distal end of the protrusion different from each other, it is possible to adjust the shape of the protrusion to a shape corresponding to each requirement, such as being able to easily adjust the length of the protrusion to the target length or being able to form the protrusion in a shape that can suppress the influence on the natural frequency of the higher-order vibration mode.

### Technology 5

The tuning-fork-type driving element according to any one of technologies 1 to 4, wherein the protrusion is integrally formed with the arm part.

According to this technology, the protrusions and the arm parts can be formed simultaneously in the same manufacturing process, so that the protrusion can be easily formed on each arm part.

### Technology 6

The tuning-fork-type driving element according to any one of technologies 1 to 5, wherein the protrusion is provided only on an inner surface of the arm part on the coupling part side.

According to this technology, since no protrusion protrudes on the outer side of each arm part, the outer width of the tuning-fork-type driving element can be reduced.

### Technology 7

The tuning-fork-type driving element according to any one of technologies 1 to 5, wherein the protrusion is provided on each of an inner surface of the arm part on the coupling part side and an outer surface of the arm part on a side opposite to the inner surface.

According to this technology, the natural frequency of the lower-order vibration mode can be appropriately adjusted while the length and the width of each protrusion are adjusted in accordance with the respective constraints of the inner side and the outer side of the arm part.

### Technology 8

The tuning-fork-type driving element according to any one of technologies 1 to 7, wherein the drive part has a piezoelectric thin film as a drive source.

According to this technology, each arm part can be smoothly driven.

### Technology 9

The tuning-fork-type driving element according to any one of technologies 1 to 8, wherein
two drive units each including the coupling part, the pair of arm parts, the support part, and the drive parts are placed in orientations opposite to each other with the movable part located therebetween, and
the coupling part of each of the drive units is connected to the movable part.

According to this technology, the movable part can be stably driven with a larger torque by each drive unit supporting and driving the movable part.

### Technology 10

A light deflection element including:
the tuning-fork-type driving element according to any one of technologies 1 to 9; and
a reflection surface located on the movable part.

According to this technology, since the light deflection element includes the tuning-fork-type driving element configured as described above, the reflection surface can be smoothly and stably vibrated in the higher-order vibration mode. Therefore, light incident on the reflection surface can be stably deflected as the movable part vibrates.

### Technology 11

A tuning-fork-type driving element including:
a pair of arm parts placed with a rotation axis located therebetween;
a support part coupling the pair of arm parts to a fixation part; and
drive parts placed on the arm parts, respectively, wherein
the pair of arm parts each have a protrusion that overlaps a node line that occurs when the arm parts vibrate in a higher-order vibration mode higher than a first-order vibration mode or an extension line of the node line, or a recess that overlaps the node line.

### Technology 12

The tuning-fork-type driving element according to technology 11, wherein the protrusion is configured to vibrate together with the arm part without being restricted by another element other than the arm part.

### Technology 13

The tuning-fork-type driving element according to technology 11 or 12, wherein the protrusion extends along the extension line of the node line.

### Technology 14

The tuning-fork-type driving element according to any one of technologies 11 to 13, wherein the protrusion has a width at a base thereof different from a width at a distal end thereof.

### Technology 15

The tuning-fork-type driving element according to any one of technologies 11 to 14, wherein the protrusion is integrally formed with the arm part.

### Technology 16

The tuning-fork-type driving element according to any one of technologies 11 to 15, wherein the protrusion is provided only on an inner surface of the arm part on the rotation axis side.

### Technology 17

The tuning-fork-type driving element according to any one of technologies 11 to 15, wherein the protrusion is provided on each of an inner surface of the arm part on the rotation axis side and an outer surface of the arm part on a side opposite to the inner surface.

### Technology 18

The tuning-fork-type driving element according to any one of technologies 11 to 17, wherein the drive part has a piezoelectric thin film as a drive source.

According to technologies 11 to 18, the same effects as those of technologies 1 to 8 are achieved

### Technology 19

The tuning-fork-type driving element according to any one of technologies 11 to 18, further including:
a movable part rotatable about the rotation axis; and
a coupling part extending from the movable part along the rotation axis and coupled to the fixation part.

### Technology 20

The tuning-fork-type driving element according to technology 19, wherein
two drive units each including the coupling part, the pair of arm parts, the support part, and the drive parts are placed in orientations opposite to each other with the movable part located therebetween, and
the coupling part of each of the drive units is connected to the movable part.

According to this technology, the same effects as those of technology 9 are achieved.

### Technology 21

A light deflection element including:
the tuning-fork-type driving element according to technology 19 or 20; and
a reflection surface located on the movable part.

According to this technology, the same effects as those of technology 10 are achieved.

What is claimed is:

1. A tuning-fork-type driving element comprising:
a movable part rotatable about a rotation axis;
a coupling part extending from the movable part along the rotation axis;
a pair of arm parts placed with the coupling part located therebetween;
a support part coupling the coupling part and the pair of arm parts to a fixation part; and
drive parts placed on the arm parts, respectively, wherein
the pair of arm parts each have a protrusion that overlaps a node line that occurs when the arm parts vibrate in a higher-order vibration mode higher than a first-order vibration mode or an extension line of the node line.

2. The tuning-fork-type driving element according to claim 1, wherein the protrusion is configured to vibrate together with the arm part without being restricted by another element other than the arm part.

3. The tuning-fork-type driving element according to claim 1, wherein the protrusion extends along the extension line of the node line.

4. The tuning-fork-type driving element according to claim 1, wherein the protrusion has a width at a base thereof different from a width at a distal end thereof.

5. The tuning-fork-type driving element according to claim 1, wherein the protrusion is integrally formed with the arm part.

6. The tuning-fork-type driving element according to claim 1, wherein the protrusion is provided only on an inner surface of the arm part on the coupling part side.

7. The tuning-fork-type driving element according to claim 1, wherein the protrusion is provided on each of an inner surface of the arm part on the coupling part side and an outer surface of the arm part on a side opposite to the inner surface.

8. The tuning-fork-type driving element according to claim 1, wherein the drive part has a piezoelectric thin film as a drive source.

9. The tuning-fork-type driving element according to claim 1, wherein
two drive units each including the coupling part, the pair of arm parts, the support part, and the drive parts are placed in orientations opposite to each other with the movable part located therebetween, and
the coupling part of each of the drive units is connected to the movable part.

10. A tuning-fork-type driving element comprising:
a pair of arm parts placed with a rotation axis located therebetween;
a support part coupling the pair of arm parts to a fixation part; and
drive parts placed on the arm parts, respectively, wherein
the pair of arm parts each have a protrusion that overlaps a node line that occurs when the arm parts vibrate in a higher-order vibration mode higher than a first-order vibration mode or an extension line of the node line, or a recess that overlaps the node line.

11. The tuning-fork-type driving element according to claim 10, wherein the protrusion is configured to vibrate together with the arm part without being restricted by another element other than the arm part.

12. The tuning-fork-type driving element according to claim 10, wherein the protrusion extends along the extension line of the node line.

13. The tuning-fork-type driving element according to claim 10, wherein the protrusion has a width at a base thereof different from a width at a distal end thereof.

14. The tuning-fork-type driving element according to claim 10, wherein the protrusion is integrally formed with the arm part.

15. The tuning-fork-type driving element according to claim 10, wherein the protrusion is provided only on an inner surface of the arm part on the rotation axis side.

16. The tuning-fork-type driving element according to claim 10, wherein the protrusion is provided on each of an inner surface of the arm part on the rotation axis side and an outer surface of the arm part on a side opposite to the inner surface.

17. The tuning-fork-type driving element according to claim 10, wherein the drive part has a piezoelectric thin film as a drive source.

18. The tuning-fork-type driving element according to claim 10, further comprising:
a movable part rotatable about the rotation axis; and
a coupling part extending from the movable part along the rotation axis and coupled to the fixation part.

19. A light deflection element comprising:
a movable part rotatable about a rotation axis;
a reflection surface located on the movable part;
a pair of arm parts placed with the rotation axis located therebetween;
a support part coupling the pair of arm parts to a fixation part;
drive parts placed on the arm parts, respectively; and
a coupling part extending from the movable part along the rotation axis and coupled to the fixation part, wherein
the pair of arm parts each have a protrusion that overlaps a node line that occurs when the arm parts vibrate in a higher-order vibration mode higher than a first-order vibration mode or an extension line of the node line, or a recess that overlaps the node line.
